(19) United States
(12) Patent Application Publication
(10) Pub. No.: US 2024/0312976 A1
(43) Pub. Date: Sep. 19, 2024

(54) SEMICONDUCTOR DEVICE AND MANUFACTURING METHOD OF SEMICONDUCTOR DEVICE

(71) Applicant: Kioxia Corporation, Tokyo (JP)

(72) Inventor: Keiichi NIWA, Yokkaichi Mie (JP)

(21) Appl. No.: 18/596,514

(22) Filed: Mar. 5, 2024

(30) Foreign Application Priority Data
Mar. 16, 2023 (JP) 2023-042392

(51) Int. Cl. H01L 25/00; H01L 21/56; H01L 23/00; H01L 23/31; H01L 25/18; H10B 80/00

(52) U.S. Cl. CPC H01L 25/50; H01L 21/563; H01L 23/3135; H01L 24/29; H01L 24/32; H01L 24/48; H01L 24/73; H01L 24/83; H01L 24/85; H01L 25/18; H10B 80/00; H01L 24/13; H01L 24/16; H01L 24/33; H01L 24/49; H01L 24/81; H01L 24/92; H01L 2224/13111; H01L 2224/13139; H01L 2224/13144; H01L 2224/13147; H01L 2224/13155; H01L 2224/13164; H01L 2224/16227; H01L 2224/2919; H01L 2224/32052; H01L 2224/32145; H01L 2224/32225; H01L 2224/33181; H01L 2224/48091; H01L 2224/48108; H01L 2224/48227; H01L 2224/49171; H01L 2224/73204; H01L 2224/73215; H01L 2224/73265; H01L 2224/81815; H01L 2224/83102; H01L 2224/83856; H01L 2224/83862; H01L 2224/85205; H01L 2224/92125; H01L 2224/92147; H01L 2924/0665

(57) ABSTRACT

A semiconductor device includes a wiring board including first and second surfaces opposite to each other, a first semiconductor element on the first surface side of the wiring board, a second semiconductor element adjacent to the first semiconductor element on the first surface side of the wiring board, a first resin composition on the first surface side of the wiring board, and a second resin composition that covers the first and second semiconductor elements and the first resin composition. The first resin composition includes a first part between the first surface of the wiring board and a surface of the first semiconductor element facing the first surface, and a second part contacting a first side surface of the second semiconductor element facing the first semiconductor element.

### CROSS-REFERENCE TO RELATED APPLICATION(S)

This application is based upon and claims the benefit of priority from Japanese Patent Application No. 2023-042392, filed Mar. 16, 2023, the entire contents of which are incorporated herein by reference.

### FIELD

Embodiments described herein relate generally to a semiconductor device and a manufacturing method of a semiconductor device.

### BACKGROUND

In a package in which a plurality of NAND flash memory chips are stacked, the NAND flash memory chips are disposed on a wiring board and sealed with a sealing resin. For example, it is possible to prevent the deformation of the package by using a thick sealing resin.

### BRIEF DESCRIPTION OF THE DRAWINGS

FIG. 1 is a schematic cross-sectional view of a semiconductor device according to an embodiment.

FIG. 2 is a schematic top view of the semiconductor device.

FIG. 3 is a flow chart of a manufacturing method of the semiconductor device.

FIG. 4 is a schematic step diagram illustrating the manufacturing method of the semiconductor device.

FIG. 5 is a schematic step diagram illustrating the manufacturing method of the semiconductor device.

FIG. 6 is a schematic step diagram illustrating the manufacturing method of the semiconductor device.

FIG. 7 is a schematic step diagram illustrating the manufacturing method of the semiconductor device.

FIG. 8 is a schematic step diagram illustrating the manufacturing method of the semiconductor device.

FIG. 9 is a schematic step diagram illustrating the manufacturing method of the semiconductor device.

FIG. 10 is a schematic step diagram illustrating the manufacturing method of the semiconductor device.

FIG. 11 is a schematic cross-sectional view of a semiconductor device according to an embodiment.

FIG. 12 is a schematic cross-sectional view of a semiconductor device according to an embodiment.

FIG. 13 is a schematic cross-sectional view of a semiconductor device according to an embodiment.

FIG. 14 is a schematic top view of a semiconductor device according to an embodiment.

FIG. 15 is a schematic top view of a semiconductor device according to an embodiment.

FIG. 16 is a schematic top view of a semiconductor device according to an embodiment.

FIG. 17 is a schematic top view of a semiconductor device according to an embodiment.

FIG. 18 is a schematic top view of a semiconductor device according to an embodiment.

FIG. 19 is a schematic top view of a semiconductor device according to an embodiment.

FIG. 20 is a schematic cross-sectional view of a semiconductor device according to an embodiment.

FIG. 21 is a schematic cross-sectional view of a semiconductor device according to an embodiment.

FIG. 22 is a schematic cross-sectional view of a semiconductor device according to an embodiment.

FIG. 23 is a schematic cross-sectional view of a semiconductor device according to an embodiment.

FIG. 24 is a schematic top view of a semiconductor device according to an embodiment.

### DETAILED DESCRIPTION

Embodiments provide a highly reliable semiconductor device and a manufacturing method of a highly reliable semiconductor device.

In general, according to one embodiment, a semiconductor device includes a wiring board including first and second surfaces opposite to each other, a first semiconductor element on the first surface side of the wiring board, a second semiconductor element adjacent to the first semiconductor element on the first surface side of the wiring board, a first resin composition on the first surface side of the wiring board, and a second resin composition that covers the first and second semiconductor elements and the first resin composition. The first resin composition includes a first part between the first surface of the wiring board and a surface of the first semiconductor element facing the first surface, and a second part contacting a first side surface of the second semiconductor element facing the first semiconductor element.

Hereinafter, embodiments will be described with reference to the drawings. In the drawings, the same reference numerals are partially omitted.

In the present specification, some elements are provided with a plurality of example expressions. It should be noted that these examples of expressions are merely examples, and it does not deny that the above-described elements are expressed by other expressions. In addition, the elements not provided with a plurality of expressions may also be expressed by different expressions.

Moreover, the drawings are schematic, and a relationship between a thickness and a planar dimension, a ratio of thicknesses of layers, and the like may differ from the reality. In addition, the drawings may have portions where a relationship and a ratio of dimensions are different from each other. Moreover, a part of reference numerals is omitted in the drawings.

The physical property values represented in the embodiment described below are values under atmospheric pressure (i.e., 1 atm) and room temperature (i.e., 25° C.).

In the present specification, steps include not only independent steps, but also combinations with other steps and other types of treatment. In numerical conditions in the present specification, when a plurality of numerical ranges are described, an upper limit or a lower limit of the numerical range may be replaced with an upper limit or a lower limit of another numerical range. When the upper limit and the lower limit of the numerical conditions in the present specification are described, the upper limit and the lower limit may be replaced with the condition of the numerical range in which the upper limit and the lower limit are combined.

### First Embodiment

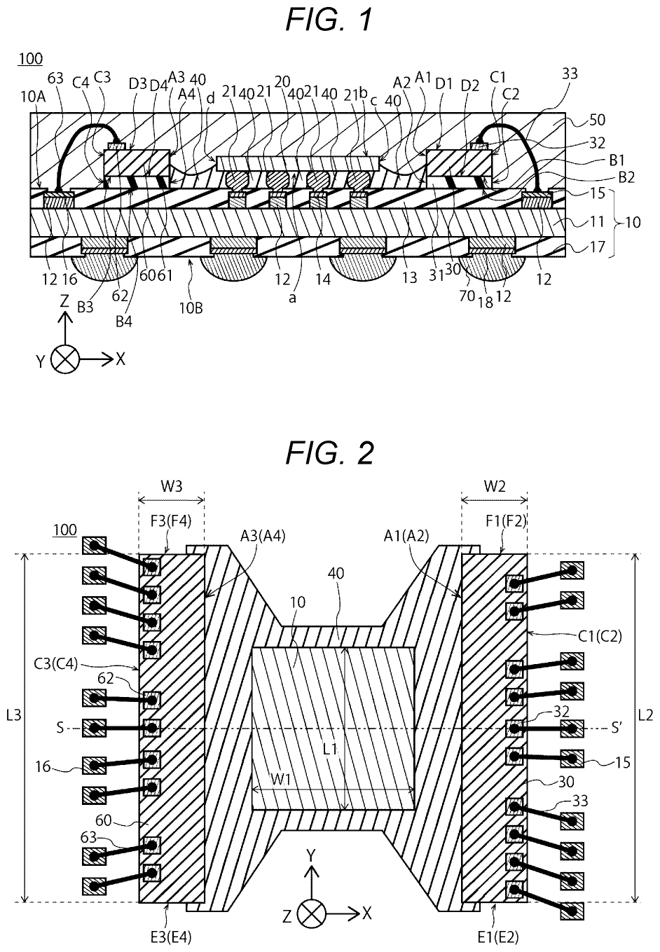

A first embodiment relates to a semiconductor device 100 and a manufacturing method of the semiconductor device 100. FIG. 1 shows a schematic cross-sectional view of the semiconductor device 100. FIG. 2 shows a schematic top view of the semiconductor device 100. The schematic top view of FIG. 2 is a view of the semiconductor device 100 as viewed from above in a Z direction of FIG. 1. The schematic view of FIG. 2 shows an upper surface of the semiconductor device 100 in which a first insulating layer 13, a second resin composition 50, and the like are invisible. More specifically, the semiconductor device 100 according to the present embodiment of FIG. 1 is a semiconductor package on which a NAND flash memory chip or the like is mounted. It should be noted that it is preferable that an X direction, a Y direction, and the Z direction intersect each other and are orthogonal to each other.

The cross-sectional view of FIG. 1 is a cross-sectional view of the vicinity of the center of the semiconductor device 100. In an actual semiconductor device, only one bonding wire may exist in one cross section.

The schematic top view of FIG. 2 shows the surfaces of the second semiconductor element 30, the third semiconductor element 60, the first intermediate layer 31, and the second intermediate layer 61. The schematic cross-sectional view of FIG. 1 is, for example, a cross-sectional view of the semiconductor device 100 along the two-point long chain line of S-S′ of FIG. 2.

The semiconductor device 100 is an example of a memory device. The semiconductor device 100 includes a wiring board 10, a first semiconductor element 20, a conductive bonding agent 21, the second semiconductor element 30, the first intermediate layer 31, a first bonding wire 33, the third semiconductor element 60, the second intermediate layer 61, a second bonding wire 63, a first resin composition 40, the second resin composition 50, and a solder ball 70.

The wiring board 10 is a substrate for the first semiconductor element 20 and the like. The wiring board 10 is more specifically a multilayer printed circuit board (PCB). Two principal surfaces of the wiring board 10 will be referred to as a first surface 10A and a second surface 10B. In the drawing, a leader line with an arrow tip indicates a reference numeral assigned to a surface of a member. On the first surface 10A, the first semiconductor element 20, the second semiconductor element 30, and the like are disposed. A hemispherical electrode such as the solder ball 70 serving as a connection terminal to the outside of the semiconductor device 100 is provided on the second surface 10B side of the wiring board 10 opposite to the first surface 10A.

The wiring board 10 has a substrate 11 on which a wiring 12 is provided. The wiring 12 electrically connects the first semiconductor element 20, the second semiconductor element 30, the third semiconductor element 60, and the like on the first surface 10A side to the solder ball 70. The first insulating layer 13 such as a resist is provided on the first surface 10A side. In openings of the first insulating layer 13, a first pad 14, a second pad 15, and a third pad 16 are disposed.

The first pad 14 is connected to the first semiconductor element 20 through the conductive bonding agent 21. For example, two or more first pads 14 are provided.

The second pad 15 is connected to the second semiconductor element 30 through the first bonding wire 33. For example, two or more second pads 15 are provided on the wiring 12 of the wiring board 10.

The third pad 16 is connected to the third semiconductor element 60 through the second bonding wire 63. For example, two or more third pads 16 are provided on the wiring 12 of the wiring board 10.

The solder ball 70 is provided on the second surface 10B side of the wiring board 10 opposite to the first surface 10A. The wiring 12 is provided on the substrate 11 on the second surface 10B side. A second insulating layer 17 such as a resist is provided on a surface of the wiring board 10 of the second surface 10B side. A plurality of fourth pads 18 connected to the wiring 12 and the solder ball 70 are provided in an opening of the second insulating layer 17.

The solder ball 70 is an external connection terminal electrically connected to the outside of the semiconductor device 100. When the semiconductor device 100 is a Ball Grid Array (BGA) package, a plurality of solder balls 70 are provided in the semiconductor device 100. Appropriate members are selected for the external connection terminals in accordance with a package form of the semiconductor device 100.

The first semiconductor element 20 is mounted on the wiring board 10. The first semiconductor element 20 is a semiconductor element that has a different circuit from both the second semiconductor element 30 and the third semiconductor element 60. The first semiconductor element 20 is electrically connected to the wiring board 10 through the conductive bonding agent 21 (for example, solder). The first semiconductor element 20 is electrically connected to the second semiconductor element 30 and the third semiconductor element 60 through the wiring board 10.

A surface of the first semiconductor element 20 facing the wiring board 10 side is an a-surface a (i.e., a lower surface). A surface of the first semiconductor element 20 opposite to the surface facing the wiring board 10 side is a b-surface b (i.e., an upper surface). A surface of the first semiconductor element 20 facing the second semiconductor element 30 side is a c-surface c (i.e., a side surface facing the second semiconductor element 30). A surface of the first semiconductor element 20 facing the third semiconductor element 60 is a d-surface d (i.e., a side surface facing the third semiconductor element 60). A side surface on the front side of FIG. 1 of the first semiconductor element 20 that does not face the second semiconductor element 30 and the third semiconductor element 60 is an e-surface e (i.e., a side surface that does not face the semiconductor element). A side surface on the side opposite to the front side of FIG. 1 of the first semiconductor element 20 that does not face the second semiconductor element 30 and the third semiconductor element 60 is an f-surface f (i.e., a side surface that does not face the semiconductor element).

A shape of each surface of the first semiconductor element 20 is a rectangular shape or a substantially rectangular shape. The shape of each surface of the first semiconductor element 20 is a rectangle, a square, a substantially rectangular shape, or a substantially square shape.

When the semiconductor device 100 is a memory device, the first semiconductor element 20 is, for example, a controller chip. The controller chip is a semiconductor chip that controls reading, writing, erasing, and the like of the second semiconductor element 30 and the third semiconductor element 60 (for example, a semiconductor memory chip).

The first semiconductor element 20 is a flip chip. It is preferable that the bonding wire directly connected to the first semiconductor element 20 is not provided in the semiconductor device 100. The first semiconductor element 20 is flip-chip-connected to the wiring board 10.

It is preferable that an aspect ratio of the a-surface a and the b-surface b of the first semiconductor element 20 is 1 or close to 1. A width of the first semiconductor element 20 is W1. The width W1 of the first semiconductor element 20 is an average distance between a width of the a-surface a and a width of the b-surface b. A depth (i.e., a dimension in the Y direction) of the first semiconductor element 20 is L1. The depth L1 of the first semiconductor element 20 is an average distance between a depth of the a-surface a and a depth of the b-surface b. When W1>L1, W1/L1 is preferably 1 or more and 2 or less, and more preferably 1 or more and 1.5 or less. When W1<L1, L1/W1 is preferably more than 1 and 2 or less, and more preferably more than 1 and 1.5 or less. A height of the first semiconductor element 20 is H1.

The conductive bonding agent 21 is electrically connected to the first pad 14 provided on the first surface 10A side of the wiring board 10 to which a pad (not shown) of the first semiconductor element 20 is provided. The conductive bonding agent 21 is, for example, a plurality of conductive bumps provided on the first semiconductor element 20, and is connected to both the plurality of pads of the first semiconductor element 20 and the first pad 14 of the wiring board 10. The conductive bonding agent 21 exists between the first semiconductor element 20 and the wiring board 10.

The conductive bonding agent 21 includes a Cu bump. The conductive bonding agent 21 before bonding to the wiring board 10 includes, for example, a solder mainly containing Su, an Au (including an Au alloy) bump, an Ag (including an alloy) bump, or a Cu (including a Cu alloy) bump (i.e., a Cu pillar). The surfaces of the Cu bumps are plated with Ni, Ni/Pd, and Ni/Pd/Au.

A gap exists between a plurality of conductive bonding agents 21.

The second semiconductor element 30 is mounted on the wiring board 10. The first intermediate layer 31 is provided between the second semiconductor element 30 and the wiring board 10.

The second semiconductor element 30 has a fifth pad 32. The second semiconductor element 30 is electrically connected to the wiring board 10 through the first bonding wire 33 that connects the fifth pad 32 and the second pad 15. As shown in FIG. 2, it is preferable that a plurality of fifth pads 32 are arranged in the Y direction.

A surface of the second semiconductor element 30 facing the first semiconductor element 20 side is an A1-surface A1 (i.e., a side surface facing the first semiconductor element 20). A surface of the second semiconductor element 30 facing the wiring board 10 side (i.e., the first intermediate layer 31 side) is a B1-surface B1 (i.e., a lower surface). A surface of the second semiconductor element 30 opposite to the surface facing the first semiconductor element 20 side is a C1-surface C1 (i.e., a side surface that does not face the first semiconductor element 20 and the third semiconductor element 60). A surface of the second semiconductor element 30 facing the side opposite to the wiring board 10 side is a D1-surface D1 (i.e., an upper surface). A side surface on the front side of FIG. 1 of the second semiconductor element 30 along a direction in which the first semiconductor element 20 and the second semiconductor element 30 are arranged is an E1-surface E1 (i.e., a side surface on the front side). A side surface on the rear side of FIG. 1 of the second semiconductor element 30 along the direction in which the first semiconductor element 20 and the second semiconductor element 30 are arranged is an F1-surface F1 (i.e., a side surface on the rear side).

The first intermediate layer 31 is, for example, an adhesive layer in which a die attach film (DAF) is cured. The first intermediate layer 31 includes, for example, an epoxy resin.

A surface of the first intermediate layer 31 facing the second semiconductor element 30 is in direct contact with the surface of the second semiconductor element 30 on the first intermediate layer 31 side (i.e., the wiring board 10 side). A surface of the first intermediate layer 31 facing the wiring board 10 side is in direct contact with the surface of the wiring board 10 facing the first intermediate layer 31 side. A surface of the first intermediate layer 31 facing the wiring board 10 is in direct contact with the surface of the first insulating layer 13 facing the first intermediate layer 31.

It is preferable that the surface of the first intermediate layer 31 facing the second semiconductor element 30 side is in direct contact with the entire surface of the second semiconductor element 30 on the first intermediate layer 31 side (i.e., the wiring board 10 side). It is preferable that the entire surface of the first intermediate layer 31 facing the wiring board 10 side is in direct contact with the surface of the wiring board 10 facing the first intermediate layer 31 side. It is preferable that the entire surface of the first intermediate layer 31 facing the wiring board 10 side is in direct contact with the surface of the first insulating layer 13 facing the first intermediate layer 31 side.

A surface of the first intermediate layer 31 facing the first semiconductor element 20 is an A2-surface A2 (i.e., a side surface facing the first semiconductor element 20). A surface of the first intermediate layer 31 facing the wiring board 10 is a B2-surface B2 (i.e., a lower surface). A surface of the first intermediate layer 31 opposite to the surface facing the first semiconductor element 20 side is a C2-surface C2 (i.e., a side surface that does not face the first semiconductor element 20 and the third semiconductor element 60). A surface of the first intermediate layer 31 facing the second semiconductor element 30 is a D2-surface D2 (i.e., an upper surface). A side surface on the front side of FIG. 1 of the first intermediate layer 31 along the direction in which the first semiconductor element 20 and the second semiconductor element 30 are arranged is an E2-surface E2 (i.e., a side surface on the front side). A side surface on the rear side in FIG. 1 of the first intermediate layer 31 along the direction in which the first semiconductor element 20 and the second semiconductor element 30 are arranged is an F2-surface F2 (i.e., a side surface on the rear side).

The third semiconductor element 60 is mounted on the wiring board 10. The first intermediate layer 31 is provided between the third semiconductor element 60 and the wiring board 10.

The third semiconductor element 60 has a sixth pad 62. The third semiconductor element 60 is electrically connected to the wiring board 10 through the second bonding wire 63 that connects the sixth pad 62 and the third pad 16. As shown in FIG. 2, it is preferable that a plurality of the sixth pads 62 are arranged in the Y direction.

A surface of the third semiconductor element 60 facing the first semiconductor element 20 side is an A3-surface A3 (i.e., a side surface facing the first semiconductor element 20). A surface of the third semiconductor element 60 facing the wiring board 10 side (i.e., the second intermediate layer 61 side) is a B3-surface B3 (i.e., a lower surface). A surface of the third semiconductor element 60 opposite to the surface facing the first semiconductor element 20 side is a C3-surface C3 (i.e., a side surface that does not face the first semiconductor element 20 and the second semiconductor element 30). A surface of the third semiconductor element 60 facing the side opposite to the wiring board 10 side is a D3-surface D3 (i.e., an upper surface). A side surface on the front side of FIG. 1 of the third semiconductor element 60 along the direction in which the first semiconductor element 20 and the third semiconductor element 60 are arranged is an E3-surface E3 (i.e., a side surface on the front side). A side surface on the rear side in FIG. 1 of the third semiconductor element 60 along the direction in which the first semiconductor element 20 and the third semiconductor element 60 are arranged is an F3-surface F3 (i.e., a side surface on the rear side).

The second intermediate layer 61 is, for example, an adhesive layer in which a die attach film (DAF) is cured. The second intermediate layer 61 includes, for example, an epoxy resin.

A surface of the second intermediate layer 61 facing the third semiconductor element 60 is in direct contact with the surface of the third semiconductor element 60 on the second intermediate layer 61 side (i.e., the wiring board 10 side). A surface of the second intermediate layer 61 facing the wiring board 10 is in direct contact with a surface of the wiring board 10 facing the second intermediate layer 61. A surface of the second intermediate layer 61 facing the wiring board 10 is in direct contact with a surface of the first insulating layer 13 facing the second intermediate layer 61.

It is preferable that the surface of the second intermediate layer 61 facing the third semiconductor element 60 is in direct contact with the entire surface of the third semiconductor element 60 on the second intermediate layer 61 side (i.e., the wiring board 10 side). It is preferable that the entire surface of the second intermediate layer 61 facing the wiring board 10 side is in direct contact with the surface of the wiring board 10 facing the second intermediate layer 61 side. It is preferable that the entire surface of the second intermediate layer 61 facing the wiring board 10 side is in direct contact with the surface of the first insulating layer 13 facing the second intermediate layer 61 side.

A surface of the second intermediate layer 61 facing the first semiconductor element 20 side is an A4-surface A4 (i.e., a side surface facing the first semiconductor element 20). A surface of the second intermediate layer 61 facing the wiring board 10 side is a B4-surface B4 (i.e., a lower surface). A surface of the second intermediate layer 61 opposite to the surface facing the first semiconductor element 20 side is a C4-surface C4 (i.e., a side surface that does not face the first semiconductor element 20 and the second semiconductor element 30). A surface of the second intermediate layer 61 facing the third semiconductor element 60 is a D4-surface D4 (i.e., an upper surface). A side surface on the front side of FIG. 1 of the second intermediate layer 61 along the direction in which the first semiconductor element 20 and the third semiconductor element 60 are arranged is an E4-surface E4 (i.e., a side surface on the front side). A side surface on the rear side in FIG. 1 of the second intermediate layer 61 along the direction in which the first semiconductor element 20 and the third semiconductor element 60 are arranged is an F4-surface F4 (i.e., a side surface on the rear side.

The first semiconductor element 20 is provided between the second semiconductor element 30 and the third semiconductor element 60. The second semiconductor element 30 and the third semiconductor element 60 are, for example, semiconductor memory chips. The semiconductor memory chip is a semiconductor chip that reads and writes data.

As the second semiconductor element 30 and the third semiconductor element 60, a non-volatile memory chip and a volatile memory chip may be used. A NAND memory chip, a phase change memory chip, a resistance change memory chip, a ferroelectric memory chip, a magnetic memory chip, or the like may be used as the non-volatile memory chip. A Dynamic Random Access Memory (DRAM) or the like may be used as the volatile memory chip. It is preferable that the second semiconductor element 30 and the third semiconductor element 60 are the non-volatile memory chips. It is more preferable that the second semiconductor element 30 and the third semiconductor element 60 are the NAND memory chip.

It is preferable that the semiconductor memory chips provided in the semiconductor device 100 are semiconductor chips having the same structure and the same circuit except for individual differences. For example, the second semiconductor element 30 and the third semiconductor element 60 are semiconductor memory chips having the same structure and the same circuit except for individual differences.

The first resin composition 40 is an insulating member that seals the lower surface side of the first semiconductor element 20. The first resin composition 40 is provided between the wiring board 10 and the first semiconductor element 20. The first resin composition 40 is in direct contact with the first surface 10A side of the wiring board 10. The first resin composition 40 is in direct contact with the lower surface (i.e., the a-surface a) side of the first semiconductor element 20. Further, the first resin composition 40 is also provided on the side surface of the second semiconductor element 30. The side surface of the second semiconductor element 30 provided with the first resin composition 40 is, for example, the A1-surface A1.

The first resin composition 40 includes, for example, an epoxy resin and a filler. The first resin composition 40 is, for example, an insulator in which the underfill is cured.

It is preferable that the first resin composition 40 is not exposed to an outer surface of the semiconductor device 100.

The first resin composition 40 provided between the first surface 10A side of the wiring board 10 and the surface (i.e., the a-surface a) side of the first semiconductor element 20 facing the wiring board 10 side exists in the gap between the conductive bonding agents 21.

It is preferable that the first resin composition 40 is provided on the side surface of the first semiconductor element 20 on the c-surface c side and on the side surface of the first semiconductor element 20 on the d-surface d side. The first resin composition 40 may be provided on the entire surface of the side surface of the first semiconductor element 20 on the c-surface c side and/or on the entire surface of the side surface of the first semiconductor element 20 on the d-surface d side.

It is preferable that the first resin composition 40 is provided on the side surface of the first semiconductor element 20 on the e-surface e side and on the side surface of the first semiconductor element 20 on the f-surface f side. The first resin composition 40 may be provided on the entire surface of the side surface of the first semiconductor element 20 on the e-surface e side and/or on the entire surface of the side surface of the first semiconductor element 20 on the f-surface f side.

The first resin composition 40 may also be provided on the surface of the first semiconductor element 20 on the b-surface b side. The first resin composition 40 may be provided along the side surface of the first semiconductor element 20, and may be further provided on the surface of the first semiconductor element 20 on the b-surface b side. It is preferable that the first resin composition 40 is not provided at the center of the surface of the first semiconductor element 20 on the b-surface b side. Stated another way, it is preferable that the first semiconductor element 20 is not sealed with only the first resin composition 40.

It is preferable that the first resin composition 40 is also provided on the first surface 10A side of the wiring board 10 between the first semiconductor element 20 and the second semiconductor element 30. It is preferable that the first resin composition 40 provided between the first semiconductor element 20 and the second semiconductor element 30 is in direct contact with the first resin composition 40 provided between the first semiconductor element 20 and the wiring board 10. It is preferable that the first resin composition 40 provided between the first semiconductor element 20 and the second semiconductor element 30 is in direct contact with the side surface of the second semiconductor element 30.

It is preferable that the first resin composition 40 is also provided on the side surface of the first intermediate layer 31 facing the same direction as the side surface of the second semiconductor element 30 provided with the first resin composition 40. The side surface of the first intermediate layer 31 provided with the first resin composition 40 is, for example, the A2-surface A2.

It is preferable that the first resin composition 40 is not in contact with the lower surface (i.e., the B2-surface B2) of the first intermediate layer 31. When the first resin composition 40 exists between the first intermediate layer 31 and the wiring board 10, the adhesiveness between the first intermediate layer 31 and the wiring board 10 is reduced, and the fixing strength is likely to be reduced. When the first resin composition 40 exists between the first intermediate layer 31 and the wiring board 10, the second semiconductor element 30 is likely to be provided obliquely with respect to the first surface 10A of the wiring board 10 by the thickness of the first resin composition 40.

It is preferable that the first resin composition 40 is not in direct contact with the first bonding wire 33.

When the first resin composition 40 is provided on the side surface of the second semiconductor element 30, the movement of the second semiconductor element 30 can be prevented from moving when the first bonding wire 33 is formed, more specifically, by the ultrasonic vibration when the first bonding wire 33 is formed. In the manufacturing process of the semiconductor device 100, the reliability of the first bonding wire 33 may be reduced when the second semiconductor element 30 moves. However, the first resin composition 40 can prevent the second semiconductor element 30 from moving and can improve the reliability of the connection through the first bonding wire 33.

When the aspect ratio of the second semiconductor element 30 is high, the effect of providing the first resin composition 40 on the side surface of the second semiconductor element 30 is remarkable. When the aspect ratio of the second semiconductor element 30 is high, the influence of the ultrasonic vibration is large. For example, when the second semiconductor element 30 having the aspect ratio of 3 is rotated by an angle of 1° [0] in the B1-surface B1 direction by ultrasonic vibration, a movement distance of the second semiconductor element 30 having the aspect ratio of 3 is three times a movement distance of the second semiconductor element 30 having the aspect ratio of 1. Even when the second semiconductor element 30 moves in an up-down direction by the ultrasonic vibration, the movement distance is larger as the aspect ratio is higher.

A width of the second semiconductor element 30 is W2. The width W2 of the second semiconductor element 30 is an average distance between a width of the B1-surface B1 and a width of the D1-surface D1. A depth of the second semiconductor element 30 is L2. The depth L2 of the second semiconductor element 30 is an average distance between a depth of the B1-surface B1 and a depth of the D1-surface D1. In the present embodiment, W2<L2. The aspect ratio (L2/W2) of the second semiconductor element 30 is preferably more than 1 and 10 or less. When the aspect ratio of the second semiconductor element 30 is large, the effect of providing the first resin composition 40 on the side surface of the second semiconductor element 30 is remarkable.

A height at which the first resin composition 40 is provided on the side surface of the second semiconductor element 30 (i.e., a distance at which the first resin composition 40 is in direct contact with the side surface of the second semiconductor element 30 in a stacking direction of the wiring board 10 and the first intermediate layer 31) is preferably 25% or more and 100% or less of H2, and more preferably 50% or more and 100% or less of H2. A distance at which the first resin composition 40 is in direct contact with the side surface of the second semiconductor element 30 in the stacking direction of the wiring board 10 and the first intermediate layer 31 is an average distance of a portion in which the first resin composition 40 is in direct contact with the side surface of the second semiconductor element 30.

When another semiconductor element is not further provided on the second semiconductor element 30, the height at which the first resin composition 40 is provided on the side surface of the second semiconductor element 30 is preferably 25% or more and less than 100% of H2, and more preferably 50% or more and less than 100% of H2. When another semiconductor element is not further provided on the second semiconductor element 30, the first resin composition 40 is easily formed on the fifth pad 32 connected to the first bonding wire 33 when the first resin composition 40 is provided on the upper surface (i.e., the D1-surface D1) of the second semiconductor element 30. When the first resin composition 40 is also formed on the fifth pad 32, the first bonding wire 33 may be formed or the reliability of the first bonding wire 33 may be reduced. Therefore, when another semiconductor element is not further provided on the second semiconductor element 30, the height at which the first resin composition 40 is provided on the side surface of the second semiconductor element 30 is preferably 25% or more and 95% or less of H2, and more preferably 50% or more and 90% or less of H2.

It is preferable that the first resin composition 40 is provided at a corner of the second semiconductor element 30 and is in direct contact with the second semiconductor element 30. When the first resin composition 40 is in direct contact with the corner of the second semiconductor element 30, the second semiconductor element 30 can be effectively prevented from rotating. When the first resin composition 40 is in direct contact with two or more corners of the second semiconductor element 30, the second semiconductor element 30 can be more effectively prevented from rotating. The corner of the second semiconductor element 30 is a portion in which the side surfaces of the second semiconductor element 30 are in contact with each other.

In the embodiment, the corner includes side surfaces forming the corner. That is, the first resin composition 40 provided at the corner is provided on two side surfaces forming the corner and is in direct contact with the two side surfaces.

It is preferable that a length of the first resin composition 40 provided on the side surface of the second semiconductor element 30 is long. When the aspect ratio is large, the second semiconductor element 30 can be effectively prevented from rotating by the long length of the first resin composition 40 provided on the side surface of the second semiconductor element 30. The length of the first resin composition 40 provided on the side surface of the second semiconductor element 30 is preferably 255% or more and 90% or less of (W2+L2), and more preferably 90% or more and 100% or less of (W2+L2).

It is preferable that the first resin composition 40 is not provided on the surface of the second semiconductor element 30 on the D1-surface D1 side. Stated another way, it is preferable that the second semiconductor element 30 is not sealed with only the first resin composition 40.

It is preferable that the first resin composition 40 is also provided on the side surface of the first intermediate layer 31. The first resin composition 40 can prevent the second semiconductor element 30 from moving with respect to the vibration when the first bonding wire 33 is bonded to the second semiconductor element 30 by applying the ultrasonic vibration.

It is preferable that the first resin composition 40 is provided at a corner of the first intermediate layer 31 and is in direct contact with the first intermediate layer 31. When the first resin composition 40 is in direct contact with the corner of the first intermediate layer 31, the first intermediate layer 31 can be effectively prevented from rotating. When the first resin composition 40 is in direct contact with two or more corners of the first intermediate layer 31, the first intermediate layer 31 can be more effectively prevented from rotating. The corner of the first intermediate layer 31 is a portion in which the side surfaces of the first intermediate layer 31 are in contact with each other.

It is preferable that the length of the first resin composition 40 provided on the side surface of the first intermediate layer 31 is long. When the aspect ratio is large, the first intermediate layer 31 can be effectively prevented from rotating by the long length of the first resin composition 40 provided on the side surface of the first intermediate layer 31. The length of the first resin composition 40 provided on the side surface of the second semiconductor element 30 satisfies preferably 25% or more and 90% or less of (W2+L2), and more preferably 90% or more and 100% or less of (W2+L2), and thus the length of the first resin composition 40 provided on the side surface of the first intermediate layer 31 has also a preferable value.

As shown in the cross-sectional view of FIG. 1, it is preferable that the first resin composition 40 is recessed between the c-surface c and the A1-surface A1. A height of a portion in which the height of the first resin composition 40 is the lowest between the c-surface c and the A1-surface A1 is denoted by h1. The height of the first resin composition 40 is a distance of the first resin composition 40 from the first surface 10A of the wiring board 10 in the stacking direction of the wiring board 10 and the first intermediate layer 31. A height at a position at which the highest height at an interface between the first semiconductor element 20 and the first resin composition 40 on the c-surface c side is denoted by h2. A height at a position with the highest height at an interface between the A1-surface A1 of the second semiconductor element 30 and the first resin composition 40 is denoted by h3. It is preferable that h1, h2, and h3 satisfy preferably h1<h2 and h1<h3, more preferably 1.1×h1<h2 and 1.1h1<h3, and still more preferably 1.2×h1<h2 and 1.2h1<h3.

It is preferable that the first resin composition 40 is provided on the side surface of the third semiconductor element 60. The side surface of the third semiconductor element 60 provided with the first resin composition 40 is, for example, the A3-surface A3. It is preferable that the first resin composition 40 provided between the first semiconductor element 20 and the third semiconductor element 60 is in direct contact with the first resin composition 40 provided between the first semiconductor element 20 and the wiring board 10.

It is preferable that the first resin composition 40 is also provided on the first surface 10A side of the wiring board 10 between the d-surface d side of the first semiconductor element 20 and the third semiconductor element 60. It is preferable that the first resin composition 40 provided between the first semiconductor element 20 and the third semiconductor element 60 is in direct contact with the side surface of the third semiconductor element 60.

It is preferable that the first resin composition 40 is also provided on the side surface of the second intermediate layer 61 facing the same direction as the side surface of the third semiconductor element 60 provided with the first resin composition 40. The side surface of the second intermediate layer 61 provided with the first resin composition 40 is, for example, the A4-surface A4.

It is preferable that the first resin composition 40 is not in contact with the lower surface (i.e., the B4-surface B4) of the second intermediate layer 61. When the first resin composition 40 exists between the second intermediate layer 61 and the wiring board 10, the adhesiveness between the second intermediate layer 61 and the wiring board 10 is reduced, and the fixing strength is likely to be reduced. When the first resin composition 40 exists between the second intermediate layer 61 and the wiring board 10, the third semiconductor element 60 is likely to be provided obliquely with respect to the first surface 10A of the wiring board 10 by the thickness of the first resin composition 40.

It is preferable that the first resin composition 40 is not in direct contact with the second bonding wire 63.

When the first resin composition 40 is provided on the side surface of the third semiconductor element 60, the third semiconductor element 60 can be prevented from moving, when the second bonding wire 63 is formed, more specifically, by the ultrasonic vibration when the second bonding wire 63 is formed. In the manufacturing process of the semiconductor device 100, the reliability of the second bonding wire 63 may be reduced when the third semiconductor element 60 moves. However, the first resin composition 40 can prevent the third semiconductor element 60 from moving and can improve the reliability of the connection through the second bonding wire 63.

When the aspect ratio of the third semiconductor element 60 is high, the effect of providing the first resin composition 40 on the side surface of the third semiconductor element 60 is remarkable. When the aspect ratio of the third semiconductor element 60 is high, the influence of the ultrasonic vibration is large. For example, when the third semiconductor element 60 having the aspect ratio of 3 is rotated by an angle of 1° [0] in the B1-surface B1 direction by ultrasonic vibration, a movement distance of the third semiconductor element 60 having the aspect ratio of 3 is three times a movement distance of the third semiconductor element 60 having the aspect ratio of 1. Even when the third semiconductor element 60 moves in an up-down direction by the ultrasonic vibration, the movement distance is larger as the aspect ratio is higher.

A width of the third semiconductor element 60 is W3. The width W3 of the third semiconductor element 60 is an average distance between a width of the B3-surface B3 and a width of the D3-surface D3. A depth of the third semiconductor element 60 is L3. The depth L3 of the third semiconductor element 60 is an average distance between a depth of the B3-surface B3 and a depth of the D3-surface D3. In the present embodiment, W3<L3. The aspect ratio (L3/W3) of the third semiconductor element 60 is preferably more than 1 and 10 or less. When the aspect ratio of the third semiconductor element 60 is large, the effect of providing the first resin composition 40 on the side surface of the third semiconductor element 60 is remarkable. A height of the third semiconductor element 60 is H3.

A height at which the first resin composition 40 is provided on the side surface of the third semiconductor element 60 (i.e., a distance at which the first resin composition 40 is in direct contact with the side surface of the third semiconductor element 60 in a stacking direction of the wiring board 10 and the second intermediate layer 61) is preferably 25% or more and 100% or less of H2, and more preferably 50% or more and 100% or less of H2. A distance at which the first resin composition 40 is in direct contact with the side surface of the third semiconductor element 60 in the stacking direction of the wiring board 10 and the second intermediate layer 61 is an average distance of a portion in which the first resin composition 40 is in direct contact with the side surface of the third semiconductor element 60.

When another semiconductor element is not further provided on the third semiconductor element 60, the height at which the first resin composition 40 is provided on the side surface of the third semiconductor element 60 is preferably 25% or more and less than 100% of H3, and more preferably 50% or more and less than 100% of H3. When another semiconductor element is not further provided on the third semiconductor element 60, the first resin composition 40 is easily formed on the sixth pad 62 connected to the second bonding wire 63 when the first resin composition 40 is provided on the upper surface (i.e., the D3-surface D3) of the third semiconductor element 60. When the first resin composition 40 is also formed on the sixth pad 62, the second bonding wire 63 may be formed or the reliability of the second bonding wire 63 may be reduced. Therefore, when another semiconductor element is not further provided on the third semiconductor element 60, the height at which the first resin composition 40 is provided on the side surface of the third semiconductor element 60 is preferably 25% or more and 95% or less of H3, and more preferably 50% or more and 90% or less of H3.

It is preferable that the first resin composition 40 is provided at a corner of the third semiconductor element 60 and is in direct contact with the third semiconductor element 60. When the first resin composition 40 is in direct contact with the corner of the third semiconductor element 60, the third semiconductor element 60 can be effectively prevented from rotating. When the first resin composition 40 is in direct contact with two or more corners of the third semiconductor element 60, the third semiconductor element 60 can be more effectively prevented from rotating. The corner of the third semiconductor element 60 is a portion in which the side surfaces of the third semiconductor element 60 are in contact with each other.

It is preferable that a length of the first resin composition 40 provided on the side surface of the third semiconductor element 60 is long. When the aspect ratio is large, the third semiconductor element 60 can be effectively prevented from rotating by the long length of the first resin composition 40 provided on the side surface of the third semiconductor element 60. The length of the first resin composition 40 provided on the side surface of the third semiconductor element 60 is preferably 25% or more and 90% or less of (W3+L3), and more preferably 90% or more and 100% or less of (W3+L3).

It is preferable that the first resin composition 40 is not provided on the surface of the third semiconductor element 60 on the D3-surface D3 side. Stated another way, it is preferable that the third semiconductor element 60 is not sealed with only the first resin composition 40.

It is preferable that the first resin composition 40 is also provided on the side surface of the second intermediate layer 61. The first resin composition 40 can prevent the third semiconductor element 60 from moving with respect to the vibration when the second bonding wire 63 is bonded to the third semiconductor element 60 by applying the ultrasonic vibration.

It is preferable that the first resin composition 40 is provided at a corner of the second intermediate layer 61 and is in direct contact with the second intermediate layer 61. When the first resin composition 40 is in direct contact with the corner of the second intermediate layer 61, the second intermediate layer 61 can be effectively prevented from rotating. When the first resin composition 40 is in direct contact with two or more corners of the second intermediate layer 61, the second intermediate layer 61 can be more effectively prevented from rotating. The corner of the second intermediate layer 61 is a portion in which the side surfaces of the second intermediate layer 61 are in contact with each other.

It is preferable that the length of the first resin composition 40 provided on the side surface of the second intermediate layer 61 is long. When the aspect ratio is large, the second intermediate layer 61 can be effectively prevented from rotating by the long length of the first resin composition 40 provided on the side surface of the second intermediate layer 61. The length of the first resin composition 40 provided on the side surface of the third semiconductor element 60 preferably satisfies 25% or more and 90% or less of (W3+L3), and more preferably 90% or more and 100% or less of (W3+L3), and thus the length of the first resin composition 40 provided on the side surface of the second intermediate layer 61 has also a preferable value.

As shown in the cross-sectional view of FIG. 1, it is preferable that the first resin composition 40 is recessed between the d-surface d and the A3-surface A3. A height of a portion in which the height of the first resin composition 40 is the lowest between the d-surface d and the A3-surface A3 is denoted by h4. The height of the first resin composition 40 is a distance of the first resin composition 40 from the first surface 10A of the wiring board 10 in the stacking direction of the wiring board 10 and the second intermediate layer 61. A height at a position at which the highest height at an interface between the first semiconductor element 20 and the first resin composition 40 on the d-surface d side is denoted by h5. A height at a position with the highest height at an interface between the A1-surface A1 of the third semiconductor element 60 and the first resin composition 40 is denoted by h6. It is preferable that h4, h5, and h6 satisfy preferably h4<h5 and h4<h6, more preferably 1.1×h4<h5 and 1.1h4<h6, and still more preferably 1.2×h4<h5 and 1.2h4<h6.

The first pad 14 may be in direct contact with the first resin composition 40.

It is preferable that the second pad 15, the third pad 16, the fifth pad 32, and the sixth pad 62 are not in direct contact with the first resin composition 40. When the first resin composition 40 is in direct contact with the second pad 15, the third pad 16, the fifth pad 32, and the sixth pad 62, it is difficult to form the first bonding wire 33 and the second bonding wire 63, and the reliability may be reduced.

The second resin composition 50 is an insulator provided on the first surface 10A side of the wiring board 10. The second resin composition 50 is a so-called mold resin. It is preferable that the second resin composition 50 is an exterior material of the semiconductor device 100. The second resin composition 50 includes, for example, an epoxy resin and a filler.

It is preferable that the second resin composition 50 is in direct contact with the upper surface (i.e., the b-surface b) of the first semiconductor element 20. It is preferable that the second resin composition 50 is in direct contact with the upper surface (i.e., the D1-surface D1) of the second semiconductor element 30. It is preferable that the second resin composition 50 is in direct contact with the upper surface (i.e., the D3-surface D3) of the third semiconductor element 60.

The first pad 14 is not in direct contact with the second resin composition 50.

The second pad 15, the third pad 16, the fifth pad 32, and the sixth pad 62 may be in direct contact with the second resin composition 50.

The first bonding wire 33 and the second bonding wire 63 are sealed with the second resin composition 50.

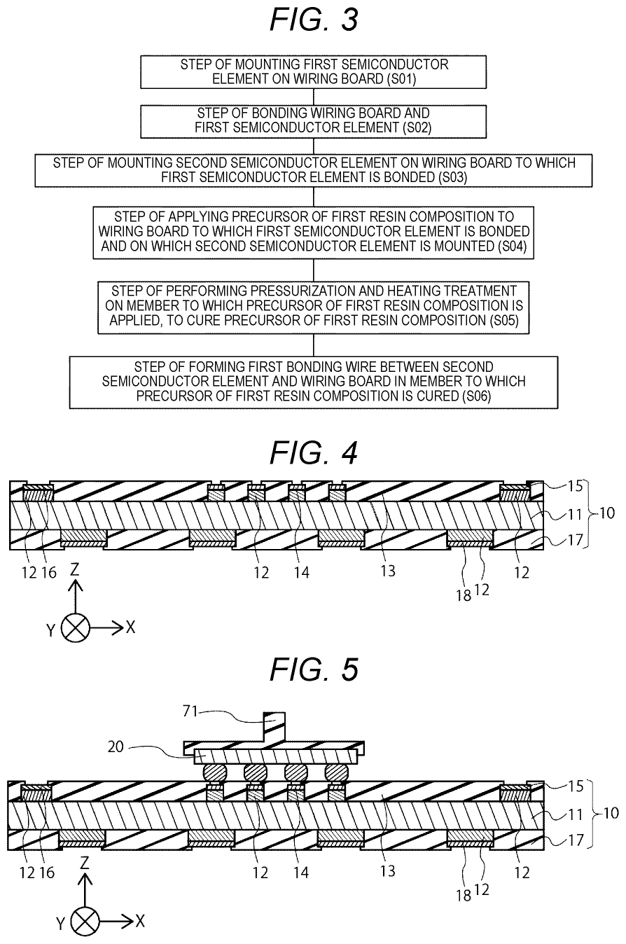

Next, the manufacturing method of the semiconductor device 100 will be described with reference to a flowchart of the manufacturing method of the semiconductor device 100 in FIG. 3 and schematic step diagrams in FIG. 4 to FIG. 10. The flowchart and the schematic step diagrams show a part of the manufacturing method of the semiconductor device 100. Although the third semiconductor element 60 is omitted in the flowchart, the description of the second semiconductor element 30 related to the manufacturing method may be applied to the third semiconductor element 60.

The manufacturing method of the semiconductor device 100 includes a step of applying a precursor of the first resin composition 40 to the wiring board 10 to which the first semiconductor element 20 is bonded and on which the second semiconductor element 30 is mounted, a step of performing pressurization and heating treatment on a member to which the precursor of the first resin composition 40 is applied, to cure the precursor of the first resin composition 40, and a step of forming the first bonding wire 33 between the second semiconductor element 30 and the wiring board 10 in the member on which the precursor of the first resin composition 40 is cured.

As shown in the flowchart of the manufacturing method of the semiconductor device 100 in FIG. 3, the manufacturing method of the semiconductor device 100 includes a step (S01) of mounting the first semiconductor element 20 on the wiring board 10, a step (S02) of bonding the wiring board 10 and the first semiconductor element 20, a step (S03) of mounting the second semiconductor element 30 on the wiring board 10 to which the first semiconductor element 20 is bonded, a step (S04) of applying the precursor of the first resin composition 40 to the wiring board 10 to which the first semiconductor element 20 is bonded and on which the second semiconductor element 30 is mounted, a step (S05) of performing the pressurization and heating treatment on the member to which the precursor of the first resin composition 40 is applied, to cure the precursor of the first resin composition 40, and a step (S06) of forming the first bonding wire 33 between the second semiconductor element 30 and the wiring board 10 in the member to which the precursor of the first resin composition 40 is cured.

The step (S01) of mounting the first semiconductor element 20 on the wiring board 10 will be described with reference to the schematic step diagrams of FIGS. 4 and 5. The schematic step diagram of FIG. 4 shows the wiring board 10. The wiring board 10 of FIG. 4 and the first semiconductor element 20 sucked by the collet 71 or the suction nozzle are mounted to obtain the member of the schematic step diagram of FIG. 5. The wiring board 10 is fixed by a clamp in which an area of the first semiconductor element 20 is open, for example. In the schematic step diagram including FIG. 4, the wiring board 10 of one semiconductor device 100 is shown, but a plurality of the same patterns are formed in horizontal and vertical directions, and are finally divided into individual pieces.

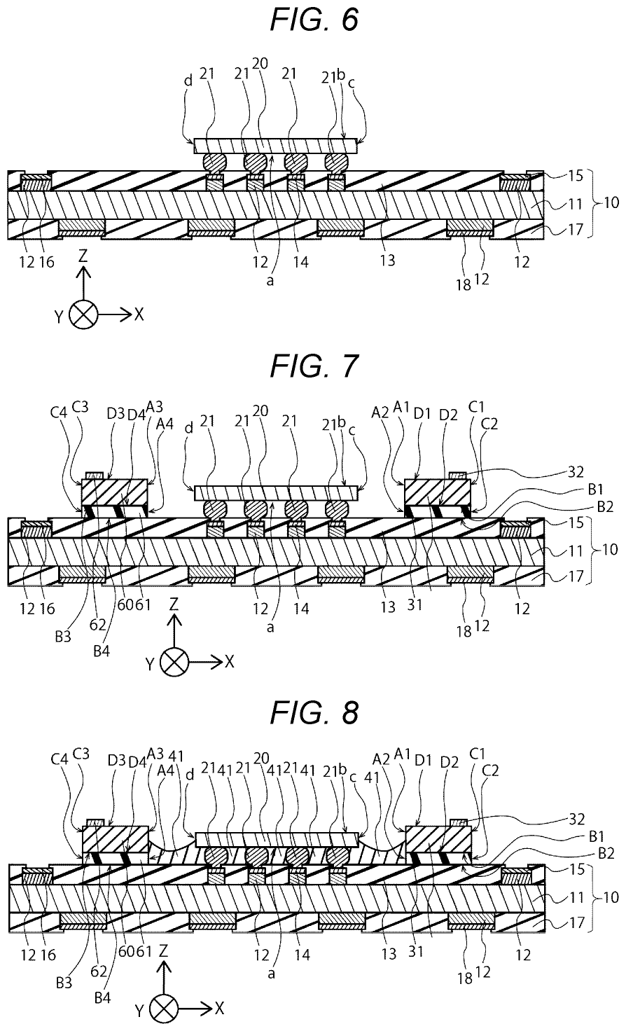

The step (S02) of bonding the wiring board 10 and the first semiconductor element 20 will be described with reference to the schematic step diagram of FIG. 6. The conductive bonding agent 21 of the member shown in the schematic step diagram of FIG. 5 is heated to bond the conductive bonding agent 21 and the first pad 14. The heating may be performed when the first semiconductor element 20 is mounted, or may be performed by heating the first semiconductor element 20 in a reflow furnace after mounting.

The step (S03) of mounting the second semiconductor element 30 on the wiring board 10 to which the first semiconductor element 20 is bonded will be described with reference to the schematic step diagram of FIG. 7. The second semiconductor element 30 and the third semiconductor element 60 are mounted on the wiring board 10 to which the first semiconductor element 20 shown in the schematic step diagram of FIG. 6 is bonded, to obtain the member shown in the schematic step diagram of FIG. 7. The first semiconductor element 20 and the third semiconductor element 60 are mounted before the precursor of the first resin composition 40 is applied.

A member in which the first intermediate layer 31 (more specifically, the first intermediate layer 31 before curing) is provided in the second semiconductor element 30 is mounted on the wiring board 10. The first intermediate layer 31 acts as the adhesive layer, and the second semiconductor element 30 is fixed to the wiring board 10. The first intermediate layer 31 may be cured in this step (S03).

A member in which the second intermediate layer 61 (more specifically, the second intermediate layer 61 before curing) is provided in the third semiconductor element 60 is mounted on the wiring board 10. The second intermediate layer 61 acts as the adhesive layer, and the third semiconductor element 60 is fixed to the wiring board 10. The second intermediate layer 61 may be cured in this step (S03).

It is preferable that the wiring board 10 is cleaned, the clamp is removed, and the wiring board 10 is fixed with a second clamp in which the areas of the second semiconductor element 30 and the third semiconductor element 60 is open, between the step (S02) of bonding the wiring board 10 and the first semiconductor element 20 and the step (S03) of mounting the second semiconductor element 30 on the wiring board 10 to which the first semiconductor element 20 is bonded.

The step (S04) of applying the precursor 41 of the first resin composition 40 to the wiring board 10 to which the first semiconductor element 20 is bonded and on which the second semiconductor element 30 is mounted will be described with reference to the schematic step diagram of FIG. 8. The underfill, which is the precursor 41 of the first resin composition 40, is applied to the member of FIG. 7. In the schematic step diagram of FIG. 8, for example, the precursor 41 of the first resin composition 40 is injected between the first semiconductor element 20 and the second semiconductor element 30 and between the first semiconductor element 20 and the third semiconductor element 60 by using a capillary. The precursor of the first resin composition 40 enters between the first semiconductor element 20 and the wiring board 10 by a capillary phenomenon and is attached to the side surfaces of the second semiconductor element 30 and the third semiconductor element 60, for example, by intermolecular force.

By adjusting the position and the amount of the precursor 41 of the first resin composition 40 injected by using the capillary, the side surfaces of the second semiconductor element 30 and the third semiconductor element 60 in which the first resin composition 40 is provided may be changed.

It is preferable to adjust an application amount and an application position of the precursor 41 of the first resin composition 40 so that the precursor 41 is not applied to the center of the upper surface of the first semiconductor element 20 and the first resin composition 40 is not provided at the center of the upper surface of the first semiconductor element 20 after curing, and to perform the pressurization and heating.

It is preferable to adjust the application amount and the application position so that the precursor 41 of the first resin composition 40 is not attached to the upper surfaces of the second semiconductor element 30 and the third semiconductor element 60 and the first resin composition 40 is not provided on the upper surfaces of the second semiconductor element 30 and the third semiconductor element 60 even after curing, and to perform the pressurization and heating.

It is preferable to adjust the application amount and the application position so that the precursor 41 of the first resin composition 40 is not attached to the second pad 15 and the third pad and the first resin composition 40 is not provided on the second pad 15 and the third pad even after curing, and to perform the pressurization and heating.

Since the precursor 41 of the first resin composition 40 does not enter between the wiring board 10 and the first intermediate layer 31 and between the wiring board 10 and the second intermediate layer 61, it is preferable that the first resin composition 40 does not exist between the wiring board 10 and the first intermediate layer 31 and between the wiring board 10 and the second intermediate layer 61 after curing.

When the precursor 41 of the first resin composition 40 is applied, a member that prevents the first resin composition 40 from spreading, for example, an insulating wall is not provided between the first semiconductor element 20 and the second semiconductor element 30 and between the first semiconductor element 20 and the third semiconductor element 60. It is preferable that a space between the first semiconductor element 20 and the second semiconductor element 30 and a space between the first semiconductor element 20 and the third semiconductor element 60 are flat. For example, a finely uneven portion may be provided between the first semiconductor element 20 and the second semiconductor element 30 and between the first semiconductor element 20 and the third semiconductor element 60. The height of a projection portion existing between the first semiconductor element 20 and the second semiconductor element 30 and between the first semiconductor element 20 and the third semiconductor element 60 (i.e., the height with respect to the surface of the wiring board 10 on which the first intermediate layer 31 is provided or the height with respect to the surface of the wiring board on which the second intermediate layer 61 is provided) is less than the height of the first intermediate layer 31, and is preferably less than the height of the second intermediate layer 61.

It is preferable that the member of the schematic step diagram of FIG. 7 is cleaned with plasma or the like before the precursor of the first resin composition 40 is applied.

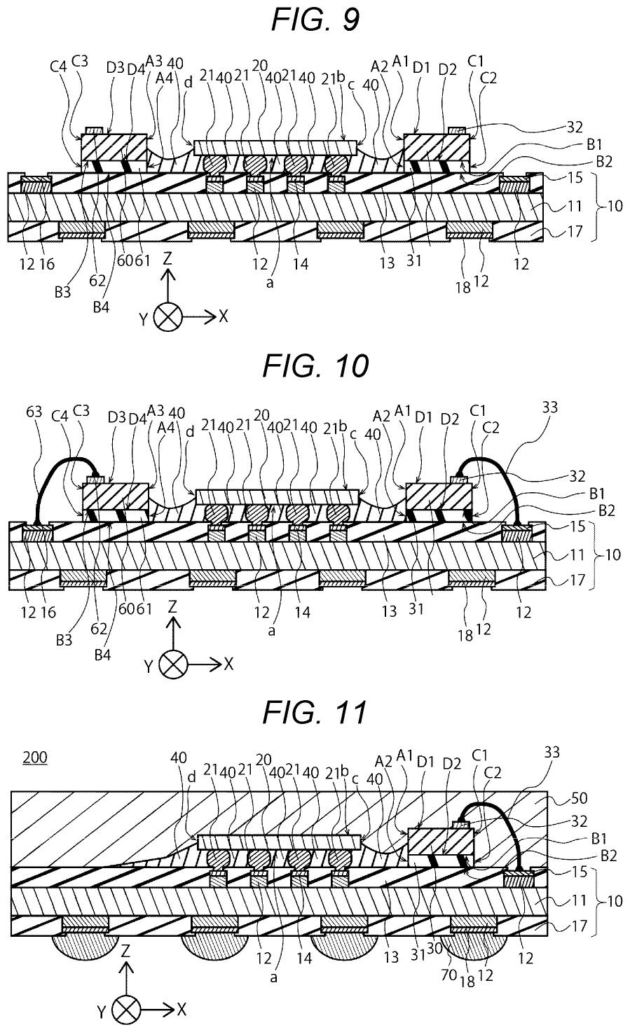

The step (S05) of performing the pressurization and heating treatment on the member on which the precursor 41 of the first resin composition 40 is applied, to cure the precursor 41 of the first resin composition 40 will be described with reference to the schematic step diagram of FIG. 9. The member of FIG. 8 is treated in a pressurization and heating atmosphere to cur the precursor 41 of the first resin composition 40, to obtain the member of FIG. 9. When the precursor 41 of the first resin composition 40 is cured, the first resin composition 40 is obtained. This curing may be incomplete curing or pre-curing. When incomplete curing is performed, it is preferable to perform re-heating and further curing (i.e., post-curing) in a subsequent step.

The first intermediate layer 31 and the second intermediate layer 61 may be cured by the pressurization and heating in this step (S05).

A depression between the first semiconductor element 20 and the second semiconductor element 30 and a depression of the first semiconductor element 20 and the third semiconductor element 60 of the first resin composition 40 are formed in the step (S04) of applying the precursor 41 of the first resin composition 40 to the wiring board 10 to which the first semiconductor element 20 is bonded and on which the second semiconductor element 30 is mounted, and/or the step (S05) of performing the pressurization and heating treatment on the member to which the precursor 41 of the first resin composition 40 is applied, to cure the precursor 41 of the first resin composition 40.

When the semiconductor element is further mounted on the second semiconductor element 30, the semiconductor element may be further mounted on the second semiconductor element 30 before and after the step (S05) of performing the pressurization and heating treatment on the member on which the precursor 41 of the first resin composition 40 is applied, to cure the precursor 41 of the first resin composition 40. When the semiconductor element is further mounted on the third semiconductor element 60, the semiconductor element may be further mounted on the third semiconductor element 60 before and after the step (S05) of performing the pressurization and heating treatment on the member on which the precursor 41 of the first resin composition 40 is applied, to cure the precursor 41 of the first resin composition 40.

When the semiconductor element is further mounted on the second semiconductor element 30 and the third semiconductor element 60 before the step (S05) of curing the precursor 41 of the first resin composition 40, the first resin composition 40 may also be provided on the side surfaces of the semiconductor elements mounted on the second semiconductor element 30 and the third semiconductor element 60. Therefore, it is preferable that the movement of the semiconductor element mounted on the second semiconductor element 30 and the third semiconductor element 60, which is caused by the ultrasonic vibration when the bonding wire is formed, is prevented.

When the semiconductor element is further mounted on the second semiconductor element 30 and the third semiconductor element 60 after the step (S05) of curing the precursor 41 of the first resin composition 40, it is preferable that the second semiconductor element 30 and the third semiconductor element 60 are difficult to move and are stable when the semiconductor element is mounted on the second semiconductor element 30 and the third semiconductor element 60. Since the second semiconductor element 30 and the third semiconductor element 60 are stable by the first resin composition 40, it is preferable that the semiconductor element mounted on the second semiconductor element 30 and the third semiconductor element is also stable. In this case, after the semiconductor element is further mounted on the second semiconductor element 30 and the third semiconductor element 60, the precursor of the first resin composition 40 is applied and cured, thereby preventing the semiconductor element mounted on the second semiconductor element 30 and the third semiconductor element 60 from moving.

The step (S06) of forming the first bonding wire 33 between the second semiconductor element 30 and the wiring board 10 in the member on which the precursor 41 of the first resin composition 40 is cured will be described with reference to the schematic step diagram of FIG. 10. The first bonding wire 33 is formed on the member of FIG. 9 between the second pad 15 on which both the first resin composition 40 and the precursor 41 of the first resin composition 40 are not formed, and the fifth pad 32 on which both the first resin composition 40 and the precursor 41 of the first resin composition 40 are not formed. In addition, the second bonding wire 63 is formed on the member of FIG. 9 between the third pad 16 on which both the first resin composition 40 and the precursor 41 of the first resin composition 40 are not formed, and the sixth pad 62 on which both the first resin composition 40 and the precursor 41 of the first resin composition 40 are not formed. The member of the schematic step diagram of FIG. 10 can be obtained by forming the first bonding wire 33 and the second bonding wire 63.

Since the first resin composition 40 is provided on the side surfaces of the second semiconductor element 30 and the third semiconductor element 60 when the first bonding wire 33 and the second bonding wire 63 are formed, the second semiconductor element 30 and the third semiconductor element 60 are prevented from moving by the ultrasonic vibration when the bonding wire is formed. When the aspect ratios of the second semiconductor element 30 and the third semiconductor element 60 are large, the movement of the second semiconductor element 30 and the third semiconductor element 60 by the ultrasonic vibration is likely to be large, but the second semiconductor element 30 and the third semiconductor element 60 by the ultrasonic vibration is prevented from moving by the first resin composition 40. Therefore, even when the second semiconductor element 30 and the third semiconductor element 60 having high aspect ratios are used, a bonding wire having high reliability can be formed.

It is preferable that both the first resin composition 40 and the precursor 41 of the first resin composition 40 are not formed on the pad to be connected, when the first bonding wire 33 and the second bonding wire 63 are formed, so that the reliability of the bonding wire is high.

The semiconductor device 100 can be manufactured by forming the second resin composition 50 on the member in the schematic step diagram of FIG. 10 and further forming the solder ball 70 on the fourth pad 18.

The semiconductor device according to the present embodiment has the following advantages in addition to the effects of preventing the movement. It is preferable that the flatness of the second semiconductor element 30 and the third semiconductor element 60 is high because the first resin composition 40 does not enter between the wiring board 10 and the first intermediate layer 31 and between the wiring board 10 and the second intermediate layer 61. It is preferable that the high flatness of the second semiconductor element 30 and the third semiconductor element 60 contributes to the improvement of the flatness of the semiconductor element mounted on the second semiconductor element 30 and the third semiconductor element 60. It is preferable that the high flatness of the second semiconductor element 30 and the third semiconductor element 60 contributes to the improvement of the reliability of the first bonding wire 33 and the second bonding wire 63. It is preferable that the high flatness of the second semiconductor element 30 and the third semiconductor element 60 also contributes to the improvement of the reliability of the bonding wire formed in the semiconductor element mounted on the second semiconductor element 30 and the third semiconductor element 60. The high flatness of the second semiconductor element 30 and the third semiconductor element 60 also contributes to the improvement of the flatness of the semiconductor device mounted on the second semiconductor element 30 and the third semiconductor element 60. From these, the high flatness of the second semiconductor element 30 and the third semiconductor element 60 contributes to the improvement of the reliability of the semiconductor device 100 and also contributes to the improvement of the yield.

### Second Embodiment

A second embodiment relates to a semiconductor device 200 and a manufacturing method of the semiconductor device 200. The semiconductor device 200 according to the second embodiment is a modification example of the semiconductor device 100 according to the first embodiment. The descriptions of the common contents in the first and second embodiments will be omitted.

A cross-sectional schematic view of the semiconductor device 200 according to the second embodiment is shown in FIG. 11. The semiconductor device 200 according to the second embodiment is similar to the semiconductor device 100 according to the first embodiment except that the third pad 16, the third semiconductor element 60, and the second bonding wire 63 are omitted.

In the manufacturing method of the semiconductor device 100 according to the first embodiment, in the step (S03) of mounting the second semiconductor element 30 on the wiring board 10 to which the first semiconductor element 20 is bonded, the third semiconductor element 60 is also mounted. However, in a manufacturing method of the semiconductor device 200 according to the second embodiment, the third semiconductor element 60 is not mounted. In addition, in the step (S06) of forming the first bonding wire 33 between the second semiconductor element 30 and the wiring board 10 in the member on which the precursor of the first resin composition 40 is cured, the second bonding wire 63 is also not formed. In addition, on the wiring board 10 of the semiconductor device 200 in which the third semiconductor element 60 is not used, the pattern and the pad for the third semiconductor element 60 may be omitted. Other than these, the manufacturing method of the semiconductor device 100 according to the first embodiment and the manufacturing method of the semiconductor device 200 according to the second embodiment are similar to each other.

According to the first embodiment and the second embodiment, it is possible to manufacture the semiconductor device 100 and the semiconductor device 200 by the similar manufacturing method. The first semiconductor element 20 of the semiconductor device 200 is not interposed between the second semiconductor element 30 and the third semiconductor element 60. A configuration is adopted in which the semiconductor memory chip is provided only on the c-surface c side of the first semiconductor element 20. The similar effects to the effects of the semiconductor device 100 according to the first embodiment can be obtained even in the semiconductor device 200 having a configuration in which the semiconductor element is mounted on one side of the first semiconductor element 20.

### Third Embodiment

A third embodiment relates to a semiconductor device 300 and a manufacturing method of the semiconductor device 300. The semiconductor device 300 according to the third embodiment is a modification example of the semiconductor device 100 according to the first embodiment and the semiconductor device 200 according to the second embodiment. A configuration of the third embodiment may be adopted in the semiconductor device 200 according to the second embodiment. The descriptions of the common contents in the first to third embodiments will be omitted.

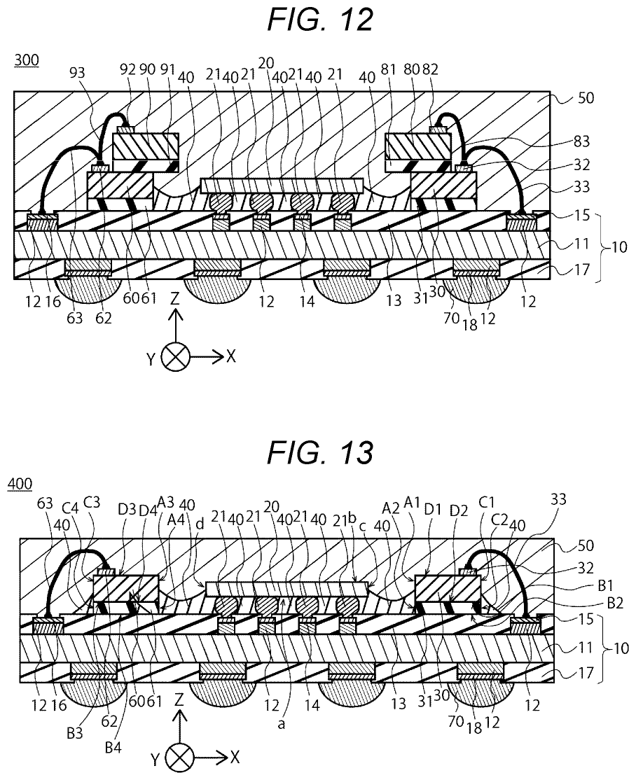

FIG. 12 shows a schematic cross-sectional view of the semiconductor device 300. The semiconductor device 300 according to the third embodiment includes a fourth semiconductor element 80 on the second semiconductor element 30, and a fifth semiconductor element 90 on the third semiconductor element 60.

The fourth semiconductor element 80 and the fifth semiconductor element 90 are, for example, semiconductor memory chips. It is preferable that the second semiconductor element 30, the third semiconductor element 60, the fourth semiconductor element 80, and the fifth semiconductor element 90 are semiconductor chips having the same structure and the same circuit except for individual differences.

The second semiconductor element 30 and the fourth semiconductor element 80 are adhered to each other in a third intermediate layer 81 existing between the fourth semiconductor element 80 and the second semiconductor element 30. A seventh pad 82 of the fourth semiconductor element 80 is connected to the fifth pad 32 of the second semiconductor element 30 through a third bonding wire 83. The fourth semiconductor element 80 is electrically connected to the first semiconductor element 20 through the third bonding wire 83, the first bonding wire 33, and the wiring board 10.

The fifth semiconductor element 90 and the third semiconductor element 60 are adhered to each other in a fourth intermediate layer 91 existing between the fifth semiconductor element 90 and the third semiconductor element 60. An eighth pad 92 of the fifth semiconductor element 90 is connected to the sixth pad 62 of the third semiconductor element 60 through a fourth bonding wire 93. The fifth semiconductor element 90 is electrically connected to the first semiconductor element 20 through the fourth bonding wire 93, the second bonding wire 63, and the wiring board 10.

It is preferable that the fourth semiconductor element 80 and the fifth semiconductor element 90 are mounted between the step (S03) of mounting the second semiconductor element 30 on the wiring board 10 to which the first semiconductor element 20 is bonded and the step (S04) of applying the precursor of the first resin composition 40 to the wiring board 10 to which the first semiconductor element 20 is bonded and on which the second semiconductor element 30 is mounted, or between the step (S05) of performing the pressurization and heating treatment on the member to which the precursor of the first resin composition 40 is applied, to cure the precursor of the first resin composition 40 and the step (S06) of forming the first bonding wire 33 between the second semiconductor element 30 and the wiring board 10 in the member to which the precursor of the first resin composition 40 is cured.

It is preferable that the third bonding wire 83 and the fourth bonding wire 93 are formed in the step (S06) of forming the first bonding wire 33 between the second semiconductor element 30 and the wiring board 10 in the member on which the precursor of the first resin composition 40 is cured.

The similar effects to the effects of the semiconductor device 100 according to the first embodiment can be obtained even in the semiconductor device 300 including the fourth semiconductor element 80 on the second semiconductor element 30 and the fifth semiconductor element 90 on the third semiconductor element 60.

### Fourth Embodiment

A fourth embodiment relates to a semiconductor device 400 and a manufacturing method of the semiconductor device 400. The semiconductor device 400 according to the fourth embodiment is a modification example of the semiconductor device 100 according to the first embodiment to the semiconductor device 300 according to the third embodiment. A configuration of the fourth embodiment may be adopted from the semiconductor device 100 according to the first embodiment to the semiconductor device 300 according to the third embodiment. The descriptions of the common contents in the first to fourth embodiments will be omitted.

In the fourth embodiment, a plurality of modification examples are shown. The fourth embodiment shows a plurality of examples of a relationship between the first resin composition 40 and the second semiconductor element 30 and a relationship between the first resin composition 40 and the third semiconductor element 60.

FIG. 13 shows a schematic cross-sectional view of the semiconductor device 400. FIG. 14 shows a schematic top view of the semiconductor device 400. The first resin composition 40 of the semiconductor device 400 according to the fourth embodiment surrounds the side surfaces of the second semiconductor element 30, the first intermediate layer 31, the third semiconductor element 60, and the second intermediate layer 61.

The first resin composition 40 is in direct contact with the A1-surface A1, the C1-surface C1, the E1-surface E1, and the F1-surface F1 of the second semiconductor element 30. Since a plurality of side surfaces and a plurality of corners of the second semiconductor element 30 are in direct contact with the first resin composition 40, the second semiconductor element 30 is effectively prevented from moving by the ultrasonic vibration.

The first resin composition 40 is in direct contact with the A2-surface A2, the C2-surface C2, the E2-surface E2, and the F2-surface F2 of the first intermediate layer 31. Since a plurality of side surfaces and a plurality of corners of the first intermediate layer 31 are in direct contact with the first resin composition 40, the first intermediate layer 31 and the second semiconductor element 30 are effectively prevented from moving by the ultrasonic vibration.

The first resin composition 40 is in direct contact with the A3-surface A3, the C3-surface C3, the E3-surface E3, and the F3-surface F3 of the third semiconductor element 60. Since a plurality of side surfaces and a plurality of corners of the third semiconductor element 60 are in direct contact with the first resin composition 40, the third semiconductor element 60 is effectively prevented from moving by the ultrasonic vibration.

The first resin composition 40 is in direct contact with the A4-surface A4, the C4-surface C4, the E4-surface E4, and the F4-surface F4 of the second intermediate layer 61. Since a plurality of side surfaces and a plurality of corners of the second intermediate layer 61 are in direct contact with the first resin composition 40, the second intermediate layer 61 and the third semiconductor element 60 are effectively prevented from moving by the ultrasonic vibration.

By adjusting the application amount and the application position of the precursor 41 of the first resin composition 40, the first resin composition 40, which surrounds the second semiconductor element 30 and the third semiconductor element 60 and is not in direct contact with the second pad 15 and the third pad 16, can be formed. In addition, since the first resin composition 40 does not exist on the lower surfaces of the first intermediate layer 31 and the second intermediate layer 61, the second semiconductor element 30 and the third semiconductor element 60 may have high flatness.

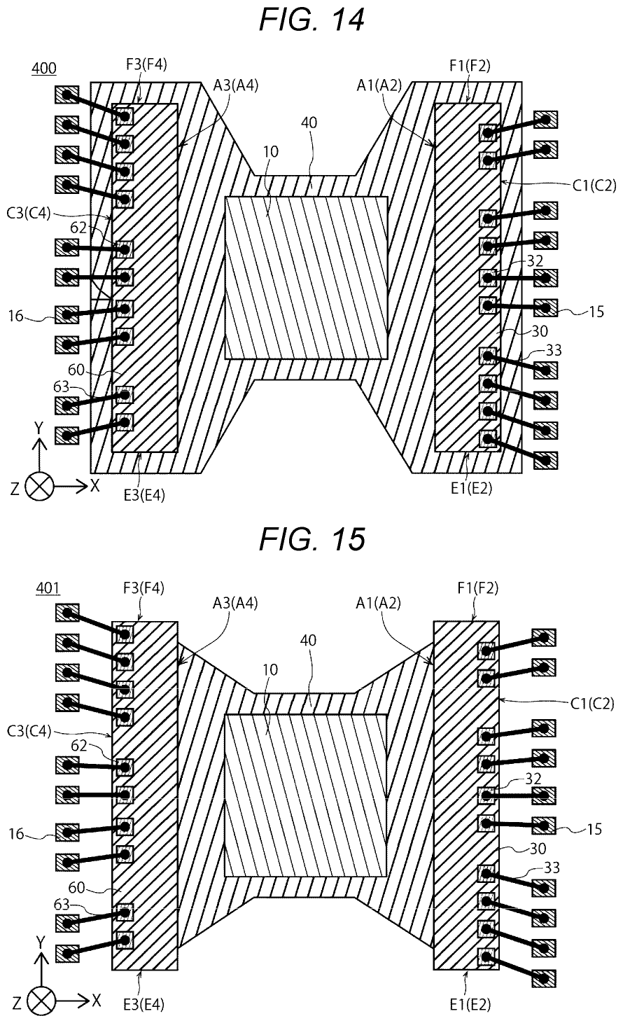

A modification example of the fourth embodiment will be described with reference to schematic top views of FIGS. 15 to 19. In any of the forms, the second semiconductor element 30 and the third semiconductor element 60 are effectively prevented from moving by the ultrasonic vibration, and the second semiconductor element 30 and the third semiconductor element 60 may have high flatness.

The first resin composition 40 of a semiconductor device 401 shown in the schematic top view of FIG. 15 is in direct contact with the A1-surface A1, which is one side surface of the second semiconductor element 30, in direct contact with the A2-surface A2, which is one side surface of the first intermediate layer 31, in direct contact with the A3-surface A3, which is one side surface of the third semiconductor element 60, and in direct contact with the A4-surface A4, which is one side surface of the second intermediate layer 61.

The first resin composition 40 of a semiconductor device 402 shown in the schematic top view of FIG. 16 is in direct contact with the A1-surface A1 of the second semiconductor element 30, the E1-surface E1 of the second semiconductor element 30, the F1-surface F1 of the second semiconductor element 30, the corner formed by the A1-surface A1 and the E1-surface E1 of the second semiconductor element 30, the corner formed by the A1-surface A1 and the F1-surface F1 of the second semiconductor element 30, the corner formed by the C1-surface C1 and the E1-surface E1 of the second semiconductor element 30, and the corner formed by the C1-surface C1 and the F1-surface F1 of the second semiconductor element 30.

The first resin composition 40 of the semiconductor device 402 is in direct contact with the A2-surface A2 of the first intermediate layer 31, the E2-surface E2 of the first intermediate layer 31, the F2-surface F2 of the first intermediate layer 31, the corner formed by the A2-surface A2 and the E2-surface E2 of the first intermediate layer 31, the corner formed by the A2-surface A2 and the F2-surface F2 of the first intermediate layer 31, the corner formed by the C2-surface C2 and the E2-surface E2 of the first intermediate layer 31, and the corner formed by the C2-surface C2 and the F2-surface F2 of the first intermediate layer 31.

The first resin composition 40 of the semiconductor device 402 is in direct contact with the A3-surface A3 of the third semiconductor element 60, the E3-surface E3 of the third semiconductor element 60, the F3-surface F3 of the third semiconductor element 60, the corner formed by the A3-surface A3 and the E3-surface E3 of the third semiconductor element 60, the corner formed by the A3-surface A3 and the F3-surface F3 of the third semiconductor element 60, the corner formed by the C3-surface C3 and the E3-surface E3 of the third semiconductor element 60, and the corner formed by the C3-surface C3 and the F3-surface F3 of the third semiconductor element 60.

The first resin composition 40 of the semiconductor device 402 is in direct contact with the A4-surface A4 of the second intermediate layer 61, the E4-surface E4 of the second intermediate layer 61, the F4-surface F4 of the second intermediate layer 61, the corner formed by the A4-surface A4 and the E4-surface E4 of the second intermediate layer 61, the corner formed by the A4-surface A4 and the F4-surface F4 of the second intermediate layer 61, the corner formed by the C4-surface C4 and the E4-surface E4 of the second intermediate layer 61, and the corner formed by the C4-surface C4 and the F4-surface F4 of the second intermediate layer 61.

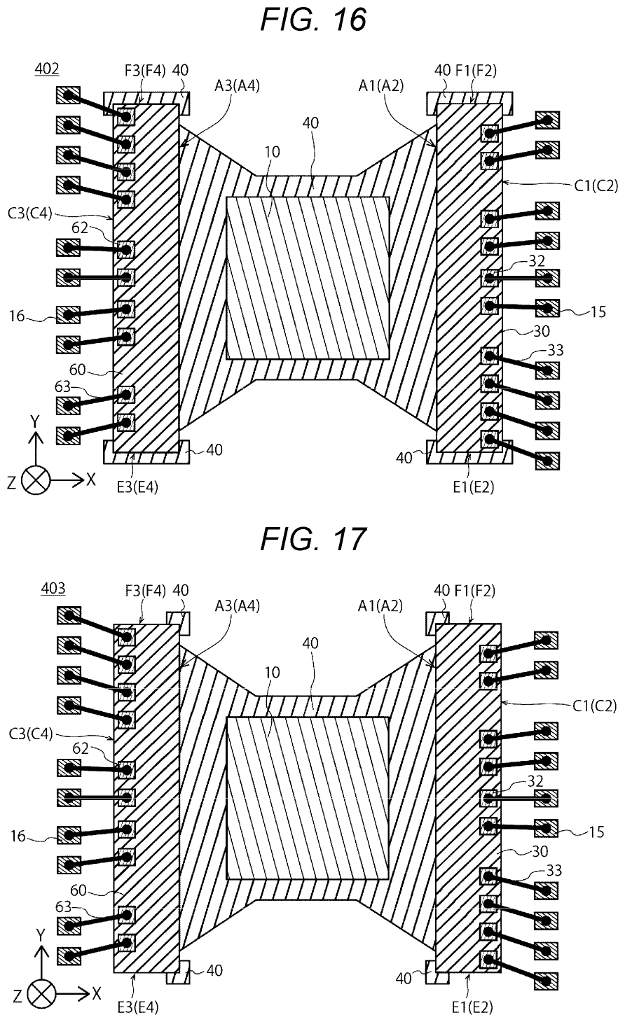

The first resin composition 40 of a semiconductor device 403 shown in the schematic top view of FIG. 17 is in direct contact with the A1-surface A1 of the second semiconductor element 30, the corner formed by the A1-surface A1 and the E1-surface E1 of the second semiconductor element 30, and the corner formed by the A1-surface A1 and the F1-surface F1 of the second semiconductor element 30.

The first resin composition 40 of the semiconductor device 403 is in direct contact with the A2-surface A2 of the first intermediate layer 31, the corner formed by the A2-surface A2 and the E2-surface E2 of the first intermediate layer 31, and the corner formed by the A2-surface A2 and the F2-surface F2 of the first intermediate layer 31.

The first resin composition 40 of the semiconductor device 403 is in direct contact with the A3-surface A3 of the third semiconductor element 60, the corner formed by the A3-surface A3 and the E3-surface E3 of the third semiconductor element 60, and the corner formed by the A3-surface A3 and the F3-surface F3 of the third semiconductor element 60.

The first resin composition 40 of the semiconductor device 403 is in direct contact with the A4-surface A4 of the second intermediate layer 61, the corner formed by the A4-surface A4 and the E4-surface E4 of the second intermediate layer 61, and the corner formed by the A4-surface A4 and the F4-surface F4 of the second intermediate layer 61.

The first resin composition 40 of a semiconductor device 404 shown in the schematic top view of FIG. 18 is in direct contact with the A1-surface A1 of the second semiconductor element 30, the corner formed by the C1-surface C1 and the E1-surface E1 of the second semiconductor element 30, and the corner formed by the C1-surface C1 and the F1-surface F1 of the second semiconductor element 30.

The first resin composition 40 of the semiconductor device 404 is in direct contact with the A2-surface A2 of the first intermediate layer 31, the corner formed by the C2-surface C2 and the E2-surface E2 of the first intermediate layer 31, and the corner formed by the C2-surface C2 and the F2-surface F2 of the first intermediate layer 31.

The first resin composition 40 of the semiconductor device 404 is in direct contact with the A3-surface A3 of the third semiconductor element 60, the corner formed by the C3-surface C3 and the E3-surface E3 of the third semiconductor element 60, and the corner formed by the C3-surface C3 and the F3-surface F3 of the third semiconductor element 60.

The first resin composition 40 of the semiconductor device 404 is in direct contact with the A4-surface A4 of the second intermediate layer 61, the corner formed by the C4-surface C4 and the E4-surface E4 of the second intermediate layer 61, and the corner formed by the C4-surface C4 and the F4-surface F4 of the second intermediate layer 61.

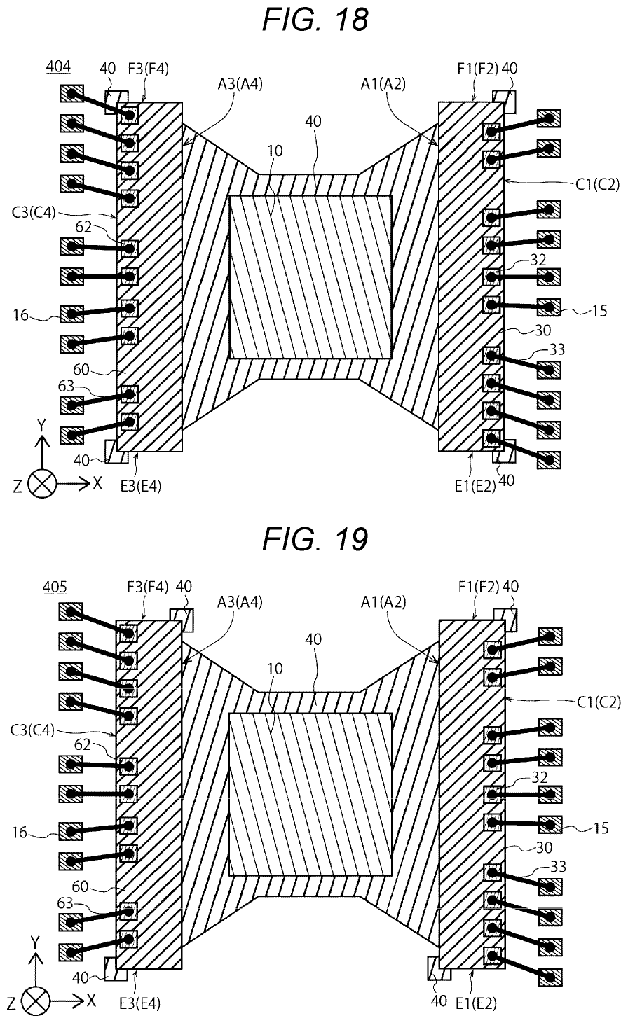

The first resin composition 40 of a semiconductor device 405 shown in the schematic top view of FIG. 19 is in direct contact with the A1-surface A1 of the second semiconductor element 30, the corner formed by the A1-surface A1 and the E1-surface E1 of the second semiconductor element 30, and the corner formed by the C1-surface C1 and the F1-surface F1 of the second semiconductor element 30.

The first resin composition 40 of the semiconductor device 405 is in direct contact with the A2-surface A2 of the first intermediate layer 31, the corner formed by the A2-surface A2 and the E2-surface E2 of the first intermediate layer 31, and the corner formed by the C2-surface C2 and the F2-surface F2 of the first intermediate layer 31.

The first resin composition 40 of the semiconductor device 405 is in direct contact with the A3-surface A3 of the third semiconductor element 60, the corner formed by the A3-surface A3 and the E3-surface E3 of the third semiconductor element 60, and the corner formed by the C3-surface C3 and the F3-surface F3 of the third semiconductor element 60.

The first resin composition 40 of the semiconductor device 405 is in direct contact with the A4-surface A4 of the second intermediate layer 61, the corner formed by the A4-surface A4 and the E4-surface E4 of the second intermediate layer 61, and the corner formed by the C4-surface C4 and the F4-surface F4 of the second intermediate layer 61.

### Fifth Embodiment

A fifth embodiment relates to a semiconductor device 500 and a manufacturing method of the semiconductor device 500. The semiconductor device 500 according to the fifth embodiment is a modification example of the semiconductor device 100 according to the first embodiment to the semiconductor devices 400 to 405 according to the fourth embodiment. More specifically, the semiconductor device 500 according to the fifth embodiment is a modification example of the semiconductor device 300 according to the third embodiment. A configuration of the fifth embodiment may be adopted from the semiconductor device 100 according to the first embodiment to the semiconductor devices 400 to 405 according to the fourth embodiment. The descriptions of the common contents in the first to fifth embodiments will be omitted.

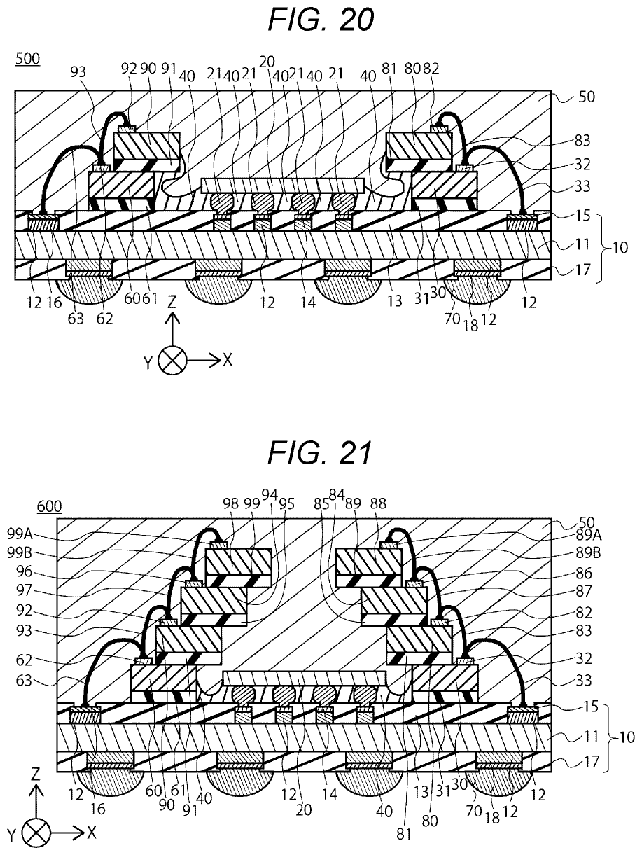

FIG. 20 shows a schematic cross-sectional view of the semiconductor device 500. The first resin composition 40 of the semiconductor device 500 according to the fifth embodiment is in direct contact with the side surfaces of the fourth semiconductor element 80, the third intermediate layer 81, the fifth semiconductor element 90, and the fourth intermediate layer 91.

Since the first resin composition 40 is also provided on the side surfaces of the fourth semiconductor element 80, the third intermediate layer 81, the fifth semiconductor element 90, and the fourth intermediate layer 91, the fourth semiconductor element 80, the third intermediate layer 81, the fifth semiconductor element 90, and the fourth intermediate layer 91 are effectively prevented from moving by the ultrasonic vibration.

By adjusting the application amount and the application position of the precursor 41 of the first resin composition 40, the semiconductor device 500 in which the first resin composition 40 is provided on the side surfaces of the fourth semiconductor element 80, the third intermediate layer 81, the fifth semiconductor element 90, and the fourth intermediate layer 91 can be manufactured. In addition, since the first resin composition 40 does not exist on the lower surfaces of the first intermediate layer 31 and the second intermediate layer 61, the first resin composition 40 is not interposed between the third intermediate layer 81 and the second semiconductor element 30, and the first resin composition 40 is not interposed between the fourth intermediate layer 91 and the third semiconductor element 60, the second semiconductor element 30, the third semiconductor element 60, the fourth semiconductor element 80, and the fifth semiconductor element 90 may have high flatness.

### Sixth Embodiment

A sixth embodiment relates to a semiconductor device 600 and a manufacturing method of the semiconductor device 600. The semiconductor device 600 according to the sixth embodiment is a modification example of the semiconductor device 100 according to the first embodiment to the semiconductor device 500 according to the fifth embodiment. More specifically, the semiconductor device 600 according to the sixth embodiment is a modification example of the semiconductor device 300 according to the third embodiment. A configuration of the sixth embodiment may be adopted from the semiconductor device 100 according to the first embodiment to the semiconductor device 500 according to the fifth embodiment. The descriptions of the common contents in the first to sixth embodiments will be omitted.

FIG. 21 shows a schematic cross-sectional view of the semiconductor device 600. The semiconductor device 600 according to the sixth embodiment includes the fourth semiconductor element 80 on the second semiconductor element 30, a sixth semiconductor element 84 on the fourth semiconductor element 80, a seventh semiconductor element 88 on the sixth semiconductor element 84, the fifth semiconductor element 90 on the third semiconductor element 60, an eighth semiconductor element 94 on the fifth semiconductor element 90, and a ninth semiconductor element 98 on the eighth semiconductor element 94.

The sixth semiconductor element 84, the seventh semiconductor element 88, the eighth semiconductor element 94, and the ninth semiconductor element 98 are, for example, semiconductor memory chips. It is preferable that the second semiconductor element 30, the third semiconductor element 60, the fourth semiconductor element 80, the fifth semiconductor element 90, the sixth semiconductor element 84, the seventh semiconductor element 88, the eighth semiconductor element 94, and the ninth semiconductor element 98 are preferably semiconductor chips having the same structure and the same circuit except for individual differences.

The fourth semiconductor element 80 and the sixth semiconductor element 84 are adhered to each other in a fifth intermediate layer 85 existing between the sixth semiconductor element 84 and the fourth semiconductor element 80. A ninth pad 86 of the sixth semiconductor element 84 is connected to the seventh pad 82 of the fourth semiconductor element 80 through a fifth bonding wire 87. The sixth semiconductor element 84 is electrically connected to the first semiconductor element 20 through the fifth bonding wire 87, the third bonding wire 83, the first bonding wire 33, and the wiring board 10.

The sixth semiconductor element 84 and the seventh semiconductor element 88 are adhered to each other in a sixth intermediate layer 89 existing between the seventh semiconductor element 88 and the sixth semiconductor element 84. A tenth pad 89A of the seventh semiconductor element 88 is connected to the ninth pad 86 of the sixth semiconductor element 84 through a sixth bonding wire 89B. The seventh semiconductor element 88 is electrically connected to the first semiconductor element 20 through the sixth bonding wire 89B, the fifth bonding wire 87, the third bonding wire 83, the first bonding wire 33, and the wiring board 10.

The eighth semiconductor element 94 and the fifth semiconductor element 90 are adhered to each other in a seventh intermediate layer 95 existing between the eighth semiconductor element 94 and the fifth semiconductor element 90. An eleventh pad 96 of the eighth semiconductor element 94 is connected to the eighth pad 92 of the fifth semiconductor element 90 through a seventh bonding wire 97. The eighth semiconductor element 94 is electrically connected to the first semiconductor element 20 through the seventh bonding wire 97, the fourth bonding wire 93, the second bonding wire 63, and the wiring board 10.

The ninth semiconductor element 98 and the eighth semiconductor element 94 are adhered to each other in an eighth intermediate layer 99 existing between the ninth semiconductor element 98 and the eighth semiconductor element 94. A twelfth pad 99A of the ninth semiconductor element 98 is connected to the eleventh pad 96 of the eighth semiconductor element 94 through an eighth bonding wire 99B. The ninth semiconductor element 98 is electrically connected to the first semiconductor element 20 through the eighth bonding wire 99B, the seventh bonding wire 97, the fourth bonding wire 93, the second bonding wire 63, and the wiring board 10.

It is preferable that the fourth semiconductor element 80, the fifth semiconductor element 90, the sixth semiconductor element 84, the seventh semiconductor element 88, the eighth semiconductor element 94, and the ninth semiconductor element 98 are mounted between the step (S03) of mounting the second semiconductor element 30 on the wiring board 10 to which the first semiconductor element 20 is bonded and the step (S04) of applying the precursor of the first resin composition 40 to the wiring board 10 to which the first semiconductor element 20 is bonded and on which the second semiconductor element 30 is mounted, or/and between the step (S05) of performing the pressurization and heating treatment on the member to which the precursor of the first resin composition 40 is applied, to cure the precursor of the first resin composition 40 and the step (S06) of forming the first bonding wire 33 between the second semiconductor element 30 and the wiring board 10 in the member to which the precursor of the first resin composition 40 is cured.

It is preferable that the third bonding wire 83, the fourth bonding wire 93, the fifth bonding wire 87, the sixth bonding wire 89B, the seventh bonding wire 97, and the eighth bonding wire 99B are formed in the step (S06) of forming the first bonding wire 33 between the second semiconductor element 30 and the wiring board 10 in the member on which the precursor of the first resin composition 40 is cured.

In the stacking direction of the first semiconductor element 20 and the wiring board 10, the semiconductor elements (for example, the sixth semiconductor element 84, the seventh semiconductor element 88, the eighth semiconductor element 94, and the ninth semiconductor element 98) are stacked on the first semiconductor element 20 of the semiconductor device 600.

The similar effects to the effects of the semiconductor device 100 according to the first embodiment can be obtained even in the semiconductor device 600 in which the four semiconductor memory chips are stacked on one side.

### Seventh Embodiment

A seventh embodiment relates to a semiconductor device 700. The semiconductor device 700 according to the seventh embodiment is a modification example of the semiconductor device 100 according to the first embodiment to the semiconductor device 600 according to the sixth embodiment. More specifically, the semiconductor device 700 according to the seventh embodiment is a modification example of the semiconductor device 100 according to the first embodiment. A configuration of the seventh embodiment may be adopted from the semiconductor device 100 according to the first embodiment to the semiconductor device 600 according to the sixth embodiment. The descriptions of the common contents in the first to seventh embodiments will be omitted.

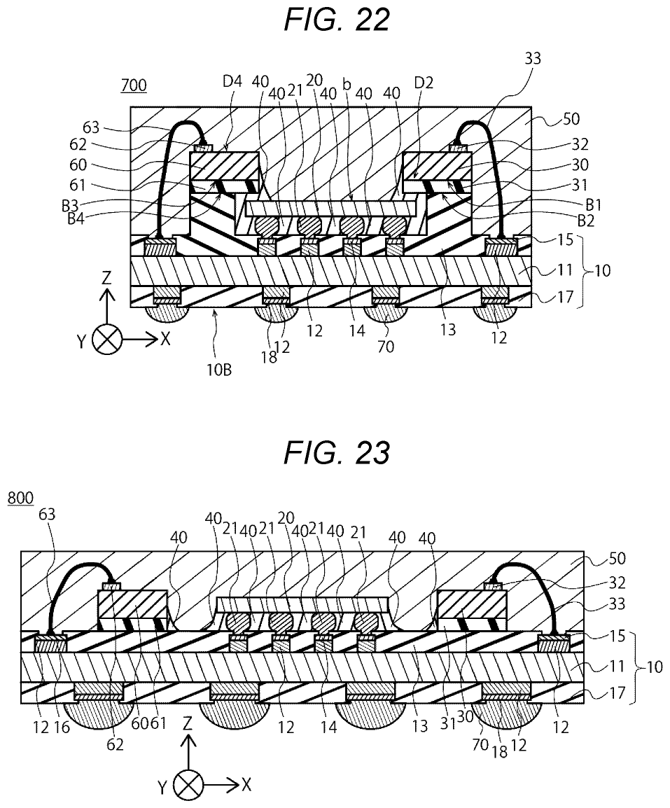

FIG. 22 shows a schematic cross-sectional view of the semiconductor device 700. In the semiconductor device 700 according to the seventh embodiment, in the stacking direction of the first semiconductor element 20 and the wiring board 10, the lower surface (i.e., the B1-surface B1) of the second semiconductor element 30, the lower surface (i.e., the B2-surface B2) of the first intermediate layer 31, the lower surface (i.e., the B3-surface B3) of the third semiconductor element 60, and the lower surface (i.e., the B4-surface B4) of the second intermediate layer 61 are farther from the second surface 10B side of the wiring board 10 than the upper surface (i.e., the b-surface b) of the first semiconductor element 20.

For example, a projection portion is provided in the first insulating layer 13 of the wiring board 10 below the second semiconductor element 30, and the second semiconductor element 30 and the third semiconductor element 60 are supported on the projection portion. The projection portion of the first insulating layer 13 is, for example, an insulating film such as a thick resist film or a polyimide. The projection portion is an example of the semiconductor device in which, in the stacking direction of the first semiconductor element 20 and the wiring board 10, the lower surface (i.e., the B1-surface B1) of the second semiconductor element 30, the lower surface (i.e., the B2-surface B2) of the first intermediate layer 31, the lower surface (i.e., the B3-surface B3) of the third semiconductor element 60, and the lower surface (i.e., the B4-surface B4) of the second intermediate layer 61 are farther from the second surface 10B side of the wiring board 10 than the upper surface (i.e., the b-surface b) of the first semiconductor element 20, and the configuration for achieving this is not limited to the projection portion.

In the stacking direction of the first semiconductor element 20 and the wiring board 10, the second semiconductor element 30 and the third semiconductor element 60 are stacked on the first semiconductor element 20 of the semiconductor device 600. The semiconductor device 700 can reduce the package size in the X direction and can prevent the second semiconductor element 30 and the third semiconductor element 60 from moving by the ultrasonic vibration.

A part of the first resin composition 40 is also provided on the lower surface (i.e., the B2-surface B2) of the first intermediate layer 31. In a portion in which the wiring board 10 supports the second semiconductor element 30, the first resin composition 40 does not exist between the first intermediate layer 31 and the wiring board 10 and between the second intermediate layer 61 and the wiring board 10. Therefore, the second semiconductor element 30 and the third semiconductor element 60 may have high flatness.

### Eighth Embodiment

An eighth embodiment relates to a semiconductor device 800. The semiconductor device 800 according to the eighth embodiment is a modification example of the semiconductor device 100 according to the first embodiment to the semiconductor device 700 according to the seventh embodiment. More specifically, the semiconductor device 700 according to the seventh embodiment is a modification example of the semiconductor device 100 according to the first embodiment. A configuration of the eighth embodiment may be adopted from the semiconductor device 100 according to the first embodiment to the semiconductor device 700 according to the seventh embodiment. The descriptions of the common contents in the first to eighth embodiments will be omitted.

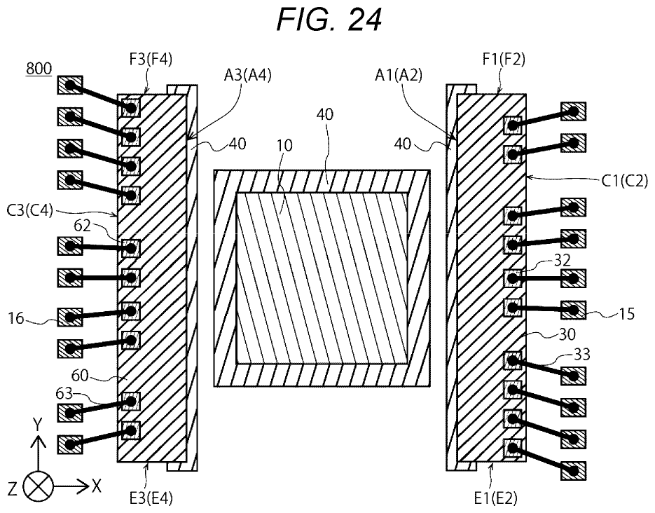

FIG. 23 shows a schematic cross-sectional view of the semiconductor device 800. FIG. 24 shows a schematic top view of the semiconductor device 800. In the semiconductor device 800 according to the eighth embodiment, the first resin composition 40 in direct contact with the first semiconductor element 20 and the first resin composition 40 in direct contact with the second semiconductor element 30 are separated from each other, and the first resin composition 40 in direct contact with the first semiconductor element 20 and the first resin composition 40 in direct contact with the third semiconductor element 60 are separated from each other.

The first semiconductor element 20 is surrounded by the first resin composition 40, and the first resin composition 40 separated from the first resin composition 40 surrounding the first semiconductor element 20 is provided on the side surface of the second semiconductor element 30, the side surface of the third semiconductor element 60, the side surface of the first intermediate layer 31, and the side surface of the second intermediate layer 61. Also in the eighth embodiment, the first resin composition 40 separated from the first semiconductor element 20 exists, and the separated first resin composition 40 is in direct contact with the corner of the second semiconductor element 30 and the corner of the third semiconductor element 60.

It is preferable that the first resin composition 40 separated from the first resin composition 40 surrounding the first semiconductor element 20 is provided on the side surface of the second semiconductor element 30 including the A1-surface A1 and the side surface of the third semiconductor element 60 including the A3-surface A3.

The first resin composition 40, which is separated from the first resin composition 40 surrounding the first semiconductor element 20 and is provided on the side surface of the second semiconductor element 30 and the side surface of the third semiconductor element 60, can prevent the second semiconductor element 30 and the third semiconductor element 60 from moving by the ultrasonic vibration.

Even when the first resin composition 40 surrounding the first semiconductor element 20 and the first resin composition 40 provided on the side surface of the second semiconductor element 30 and the side surface of the third semiconductor element 60 are separated from each other, the second semiconductor element 30 and the third semiconductor element 60 may have high flatness.

Hereinafter, the technical ideas of the manufacturing method of the semiconductor device and the semiconductor device according to the above-described embodiments will be described.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A semiconductor device comprising:
a wiring board including first and second surfaces opposite to each other;
a first semiconductor element on the first surface side of the wiring board;
a second semiconductor element adjacent to the first semiconductor element on the first surface side of the wiring board;
a first resin composition on the first surface side of the wiring board; and
a second resin composition that covers the first and second semiconductor elements and the first resin composition, wherein
the first resin composition includes:
a first part between the first surface of the wiring board and a surface of the first semiconductor element facing the first surface, and
a second part contacting a first side surface of the second semiconductor element facing the first semiconductor element.

2. The semiconductor device according to claim 1, wherein the first semiconductor element is a flip chip.

3. The semiconductor device according to claim 1, wherein the second semiconductor element and the wiring board are connected by a bonding wire.

4. The semiconductor device according to claim 1, wherein the first resin composition contacts a side surface of the first semiconductor element facing the first side surface of the second semiconductor element.

5. The semiconductor device according to claim 4, wherein the first resin composition contacts a second side surface of the second semiconductor element connected and perpendicular to the first side surface of the second semiconductor element.

6. The semiconductor device according to claim 1, further comprising:
a third semiconductor element adjacent to the first semiconductor element on the first surface side of the wiring board, wherein
the first resin composition includes a third part contacting a side surface of the third semiconductor element facing the first semiconductor element.

7. The semiconductor device according to claim 1, wherein
the first and second semiconductor elements are arranged along a first direction,
a width of the first semiconductor element in the first direction is substantially identical to a length thereof in a second direction perpendicular to the first direction,
a width of the second semiconductor element in the first direction is smaller than the width of the first semiconductor element and a length of the second semiconductor element in the second direction, and
the length of the second semiconductor element is greater than the length of the first semiconductor element.

8. The semiconductor device according to claim 7, wherein a ratio of the length of the second semiconductor element to the width thereof is between 1 and 10.

9. The semiconductor device according to claim 1, further comprising:
an intermediate layer between the first surface of the wiring board and the first semiconductor element, wherein
the first resin composition contacts a side surface of the intermediate layer facing the first semiconductor element.

10. The semiconductor device according to claim 1, wherein
the first resin composition includes a third part contacting a side surface of the first semiconductor element facing the first side surface of the second semiconductor element and a fourth part between the second and third parts of the first resin composition, and
a height of the fourth part is lower than a height of each of the second and third parts.

11. The semiconductor device according to claim 1, wherein the first resin composition includes a third part contacting a side surface of the first semiconductor element opposite to another side surface thereof facing the first side surface of the second semiconductor element, and a height of the third part gradually decreases in a direction away from the side surface of the first semiconductor element.

12. The semiconductor device according to claim 1, further comprising:
a fourth semiconductor element stacked above the second semiconductor element, wherein
when viewed in a direction perpendicular to the first surface of the wiring board, a part of the fourth semiconductor element overlaps the second part of the first resin composition.

13. The semiconductor device according to claim 1, wherein when viewed in a direction perpendicular to the first surface of the wiring board, the first and second semiconductor elements are surrounded by the first resin composition.

14. The semiconductor device according to claim 1, wherein
the second semiconductor element has a rectangular shape including four corners, and
the first resin composition includes a third part that covers one pair of the corners connected to one side of the second semiconductor element and a fourth part that covers the other pair of the corners when viewed in a direction perpendicular to the first surface of the wiring board.

15. The semiconductor device according to claim 1, wherein
the second semiconductor element has a rectangular shape including a plurality of corners, and
the first resin composition includes a third part that covers one of the corners when viewed in a direction perpendicular to the first surface of the wiring board.

16. The semiconductor device according to claim 15, wherein the first resin composition includes a fourth part that covers another one of the corners that is connected to one side to which said one of the corners is connected or that is diagonally opposite to said one of the corners.

17. The semiconductor device according to claim 15, wherein the first resin composition includes a plurality of parts each covering a corresponding one of the other three corners.

18. The semiconductor device according to claim 1, further comprising:
a fourth semiconductor element stacked above the second semiconductor element, wherein
the first resin composition contacts a side surface of the fourth semiconductor element that faces a same direction as the first side surface of the second semiconductor element.

19. A manufacturing method of a semiconductor device, the manufacturing method comprising:
mounting a first semiconductor element on a wiring board;
bonding the first semiconductor element to the wiring board;
mounting a second semiconductor element adjacent to the first semiconductor element on the wiring board;
applying a precursor of a resin composition to the wiring board such that the precursor fills a gap between a surface of the wiring board and a surface of the first semiconductor layer that face each other, and at least partly covers a side surface of the first semiconductor layer and a side surface of the second semiconductor layer that face each other;
performing pressurization and heating treatment on the wiring board to cure the precursor of the resin composition; and
forming a bonding wire between the second semiconductor element and the wiring board.

20. The manufacturing method according to claim 19, wherein the first semiconductor element is a flip chip.
